(19) United States
(12) Patent Application Publication
(10) Pub. No.: US 2026/0333689 A1
(43) Pub. Date: Oct. 22, 2026

(54) SEMICONDUCTOR DEVICE

(71) Applicant: SAMSUNG ELECTRONICS CO., LTD., Suwon-si (KR)

(72) Inventors: Sangyong PARK, Suwon-si (KR); Seungjae BAIK, Suwon-si (KR); Jaehwang SIM, Suwon-si (KR)

(73) Assignee: SAMSUNG ELECTRONICS CO., LTD., Suwon-si (KR)

(21) Appl. No.: 19/549,129

(22) Filed: Feb. 25, 2026

(30) Foreign Application Priority Data
Apr. 16, 2025 (KR) 10-2025-0049700

(51) Int. Cl. H10B 43/10; G11C 5/06; H10B 41/10; H10B 41/27; H10B 41/35; H10B 41/41; H10B 43/27; H10B 43/35; H10B 43/40; H10B 80/00; H10D 30/01; H10D 30/68; H10D 30/69; H10D 62/13; H10D 62/17; H10D 80/30; H10W 90/00

(52) U.S. Cl. CPC H10B 43/10; G11C 5/063; H10B 41/10; H10B 41/27; H10B 41/35; H10B 41/41; H10B 43/27; H10B 43/35; H10B 43/40; H10D 30/689; H10D 30/693; H10D 62/151; H10D 62/292; H10B 80/00; H10D 30/0411; H10D 30/0413; H10D 80/30; H10W 90/792

(57) ABSTRACT

A semiconductor device including a channel structure arranged in a channel hole extending in the vertical direction through the plurality of gate electrodes, wherein the channel structure includes a gate insulating layer arranged on an inner wall of the channel hole, a channel layer arranged on an inner wall of the gate insulating layer, a buried insulating layer covering a portion of an inner wall of the channel layer, a plurality of drain patterns covering the remaining portion of the inner wall of the channel layer and spaced apart from each other in a horizontal direction, and a drain region cut arranged between the plurality of drain patterns to electrically separate the plurality of drain patterns from each other, wherein one end of the drain region cut is in contact with the buried insulating layer in the vertical direction.

### CROSS-REFERENCE TO RELATED APPLICATION

This application claims priority under 35 U.S.C. § 119 to Korean Patent Application No. 10-2025-0049700, filed on Apr. 16, 2025, in the Korean Intellectual Property Office, the disclosure of which is incorporated by reference herein in its entirety.

### BACKGROUND

The inventive concept relates to a semiconductor device, and more particularly, to a semiconductor device having a vertical channel.

In electronic systems that require data storage, semiconductor devices capable of storing large amounts of data are required. Accordingly, methods capable of increasing the data storage capacity of semiconductor devices are being studied. For example, as one of the methods for increasing the data storage capacity of a semiconductor device, semiconductor devices including memory cells arranged three-dimensionally instead of memory cells arranged two-dimensionally have been proposed.

### SUMMARY

The inventive concept provides a semiconductor device having improved integration.

The task to be solved by the technical idea of the inventive concept is not limited to the above-mentioned task, and other tasks not mentioned may be clearly understood by those of ordinary skill in the art from the following description.

According to an aspect of the inventive concept, there is provided a semiconductor device including a plurality of gate electrodes and a plurality of mold insulating layers arranged alternately with each other in a vertical direction on a substrate, and a channel structure arranged in a channel hole extending in the vertical direction through the plurality of gate electrodes, wherein the channel structure includes a gate insulating layer arranged on an inner wall of the channel hole, a channel layer arranged on an inner wall of the gate insulating layer, a buried insulating layer covering a portion of an inner wall of the channel layer, a plurality of drain patterns covering the remaining portion of the inner wall of the channel layer and spaced apart from each other in a horizontal direction, and a drain region cut arranged between the plurality of drain patterns to electrically separate the plurality of drain patterns from each other, wherein one end of the drain region cut is in contact with the buried insulating layer in the vertical direction.

According to an aspect of the inventive concept, there is provided a semiconductor device including a peripheral circuit structure, and a cell structure arranged on the peripheral circuit structure, wherein the cell structure includes a plurality of gate electrodes and a plurality of mold insulating layers alternately arranged in a vertical direction on a top surface of the peripheral circuit structure, and a channel structure arranged in a channel hole extending in the vertical direction through the plurality of gate electrodes, wherein the channel structure includes a gate insulating layer arranged on an inner wall of the channel hole, a first channel pattern and a second channel pattern arranged on an inner wall of the gate insulating layer, and a buried insulating layer arranged on an inner wall of each of the first channel pattern and the second channel pattern, wherein the channel hole includes a pair of first regions facing each other in a first horizontal direction and a pair of second regions facing each other in a second horizontal direction crossing the first horizontal direction, the first channel pattern and the second channel pattern are respectively arranged on the pair of second regions of the channel hole and spaced apart from each other in the second horizontal direction, and each of the first channel pattern and the second channel pattern has a shape in which a thickness decreases from a center portion toward an edge portion in a layout.

According to an aspect of the inventive concept, there is provided a semiconductor device including a peripheral circuit structure, and a cell structure arranged on the peripheral circuit structure and including a cell region and a connection region, wherein the cell structure includes a plurality of gate electrodes and a plurality of mold insulating layers alternately arranged in a vertical direction on a top surface of the peripheral circuit structure in the cell region and the connection region, a channel structure arranged in a channel hole extending in the vertical direction through the plurality of gate electrodes in the cell region, a stack cover insulating layer arranged under a lowermost gate electrode among the plurality of gate electrodes in the cell region and the connection region, and a cell plug being in contact with a first gate electrode of the plurality of gate electrodes in the connection region, and arranged in a cell plug hole passing through a second gate electrode of the plurality of gate electrodes arranged under the first gate electrode among the plurality of gate electrodes, wherein the channel structure includes a gate insulating layer arranged on an inner wall of the channel hole, a first channel pattern and a second channel pattern arranged on an inner wall of the gate insulating layer and spaced apart from each other in a horizontal direction, a buried insulating layer arranged on an inner wall of each of the first channel pattern and the second channel pattern to cover an upper portion of the inner wall of each of the first channel pattern and the second channel pattern, a first drain pattern and a second drain pattern arranged on the inner walls of the first channel pattern and the second channel pattern to cover a lower portion of the inner walls of the first channel pattern and the second channel pattern, and spaced apart from each other in the horizontal direction, and a drain region cut separating the first drain pattern from the second drain pattern, wherein one end of the drain region cut is in contact with the buried insulating layer in the vertical direction.

According to an aspect of the inventive concept, there is provided a method of manufacturing a semiconductor device, the method including forming a mold stack by alternately stacking a plurality of gate electrodes and a plurality of mold insulating layers in a vertical direction on a substrate, forming a channel hole including a pair of first regions penetrating the mold stack in the vertical direction and facing each other in a first horizontal direction and a pair of second regions facing each other in a second horizontal direction crossing the first horizontal direction, and forming a channel structure in the channel hole, wherein the forming of the channel structure includes forming a gate insulating layer on an inner wall of the channel hole, forming a preliminary channel layer on an inner wall of the gate insulating layer, the preliminary channel layer having a first thickness on the pair of first regions of the channel hole and having a second thickness greater than the first thickness on the pair of second regions of the channel hole, isotropically etching the preliminary channel layer to form a first channel pattern and a second channel pattern spaced apart from each other on the inner wall of the gate insulating layer, and forming a buried insulating layer on an inner wall of each of the first channel pattern and the second channel pattern, wherein the first channel pattern and the second channel pattern are arranged on the pair of second regions of the channel hole, respectively.

In an embodiment, the channel hole has a second width in the second horizontal direction that is greater than a first width in the first horizontal direction.

In an embodiment, in the isotropically etching of the preliminary channel layer, the preliminary channel layer is isotropically etched to expose a portion of the gate insulating layer, and the exposed portion of the gate insulating layer is arranged on the pair of first regions of the channel hole.

In an embodiment, after the forming of the buried insulating layer, the method of manufacturing a semiconductor device further includes forming a preliminary drain region on an upper portion of the buried insulating layer, and forming a drain region cut which penetrates the preliminary drain region in the vertical direction and separates the preliminary drain region into a first drain pattern and a second drain pattern, wherein the first drain pattern is arranged between the first channel pattern and a sidewall of the drain region cut, and the second drain pattern is arranged between the second channel pattern and the other sidewall of the drain region cut.

In an embodiment, one end of the drain region cut is in contact with the buried insulating layer in the vertical direction.

In an embodiment, after the forming of the drain region cut, the method of manufacturing a semiconductor device further includes forming a plurality of bit line contacts electrically connected to the first drain pattern and the second drain pattern, respectively.

In an embodiment, the forming of the gate insulation layer includes forming a blocking dielectric layer on an inner wall of the channel hole, forming a charge storage layer on an inner wall of the blocking dielectric layer, forming a tunneling dielectric layer on an inner wall of the charge storage layer.

In an embodiment, the forming of the blocking dielectric layer includes forming a preliminary blocking dielectric layer on an inner wall of the channel hole, the preliminary blocking dielectric layer having a greater thickness on the pair of second regions of the channel hole than a thickness on the pair of first regions of the channel hole, and isotropically etching the preliminary blocking dielectric layer to form a first blocking dielectric pattern and a second blocking dielectric pattern on the inner wall of the channel hole, wherein the first blocking dielectric pattern and the second blocking dielectric pattern are arranged on the pair of second regions of the channel hole, respectively.

In an embodiment, the forming of the charge storage layer includes forming a preliminary charge storage layer on an inner wall of the blocking dielectric layer, the preliminary charge storage layer having a greater thickness on the pair of second regions of the channel hole than a thickness on the pair of first regions of the channel hole, and isotropically etching the preliminary charge storage layer to form a first charge storage pattern and a second charge storage pattern on the inner wall of the blocking dielectric layer, wherein the first charge storage pattern and the second charge storage pattern are arranged on the pair of second regions of the channel hole, respectively.

In an embodiment, the forming of the tunneling dielectric layer includes forming a preliminary tunneling dielectric layer on an inner wall of the charge storage layer, the preliminary tunneling dielectric layer having a greater thickness on the pair of second regions of the channel hole than a thickness on the pair of first regions of the channel hole, and isotropically etching the preliminary tunneling dielectric layer to form a first tunneling dielectric pattern and a second tunneling dielectric pattern on the inner wall of the charge storage layer, wherein the first tunneling dielectric pattern and the second tunneling dielectric pattern are arranged on the pair of second regions of the channel hole, respectively.

### BRIEF DESCRIPTION OF THE DRAWINGS

Embodiments will be more clearly understood from the following detailed description taken in conjunction with the accompanying drawings in which:

FIG. 1 is a block diagram of a semiconductor device according to embodiments;

FIG. 2 is an equivalent circuit diagram of a memory cell array of a semiconductor device according to embodiments;

FIG. 3 is a perspective view illustrating a representative configuration of a semiconductor device according to embodiments;

FIG. 4 is a plan view illustrating the semiconductor device of FIG. 3, according to embodiments;

FIG. 5 is a cross-sectional view taken along line A-A′ of FIG. 4;

FIG. 6 is a schematic plan view at a vertical level taken along line B-B′ of FIG. 5;

FIGS. 7A and 7B are schematic perspective views of portions indicated by “P1” in FIG. 5, respectively;

FIGS. 8A, 8B and 8C are schematic plan views for describing another embodiment at the vertical level taken along line B-B′ of FIG. 5, respectively;

FIGS. 9A and 9B are schematic plan views for describing another embodiment at the vertical level taken along line B-B′ of FIG. 5, respectively;

FIGS. 10A and 10B are schematic plan views illustrating semiconductor devices according to other embodiments, respectively;

FIG. 11 is a cross-sectional view illustrating a semiconductor device according to other embodiments;

FIG. 12 is a cross-sectional view illustrating a semiconductor device according to other embodiments;

FIG. 13 is a cross-sectional view illustrating a semiconductor device according to other embodiments;

FIGS. 14A, 14B, 14C and 14D are diagrams for describing a semiconductor device according to other embodiments;

FIGS. 15, 16A, 16B,, 17A, 17B, 18A, 18B, 19A, 19B, 20A, 20B, 21, 22, 23, 24, 25A, 25B, 26, 27, 28, 29, and 30 are cross-sectional views illustrating a method of manufacturing a semiconductor device according to embodiments, in which, in detail, FIGS. 15, 16A, 17A, 18A, 19A, 20A, and 21, 22, 23, 24, 25A, 25B, 26, 27, 28, 29, and 30 are cross-sectional views respectively corresponding to a cross-section taken along line A-A′ of FIG. 4, and FIGS. 16B, 17B, 18B, 19B, and 20B are schematic plan views respectively corresponding to a plane at a vertical level taken along line B-B′ of FIGS. 16A, 17A, 18A, 19A, and 20A;

FIG. 31 is a diagram schematically illustrating a data storage system including a semiconductor device according to embodiments;

FIG. 32 is a perspective view schematically illustrating a data storage system including a semiconductor device according to embodiments; and

FIG. 33 is a cross-sectional view schematically illustrating semiconductor packages according to embodiments.

### DETAILED DESCRIPTION OF THE EMBODIMENTS

Hereinafter, embodiments of the inventive concept will be described in detail with reference to the accompanying drawings. The same reference numerals are used for the same components in the drawings, and redundant descriptions thereof will be omitted.

In the disclosure, the horizontal direction may include a first horizontal direction (X direction) and a second horizontal direction (Y direction) crossing each other. A direction intersecting the first horizontal direction (X direction) and the second horizontal direction (Y direction) may be referred to as a vertical direction (Z direction). In the disclosure, the vertical level may be referred to as a height level according to the vertical direction (Z direction) of any configuration.

Although the terms “first,” “second,” and the like are used to describe various elements, components, and/or sections, these elements, components, and/or sections are not limited by these terms.

These terms are used only to distinguish one element, component or section from another element, component or section. Therefore, the first element, the first component, or the first section mentioned below may be the second element, the second component, or the second section within the technical idea of the present invention.

Spatially relative terms such as “above” and “below” may be used herein for convenience in describing the relationship between one element(s) and another element(s), as shown in the drawings. It will be understood that spatially relative terms are intended to include different directions of semiconductor devices in use or in operation in addition to the directions shown in the drawings. For example, if the semiconductor device is turned over in the drawings, elements depicted as “below” other elements are oriented “above” the other elements. Therefore, the term “below” may include both up and down directions. The semiconductor device may be directed in a different direction (in a direction rotating by 90 degrees or in a different direction), and the spatially relative descriptions used herein are interpreted accordingly.

The terms used in the disclosure are intended to describe embodiments and are not intended to limit the scope of the inventive concept.

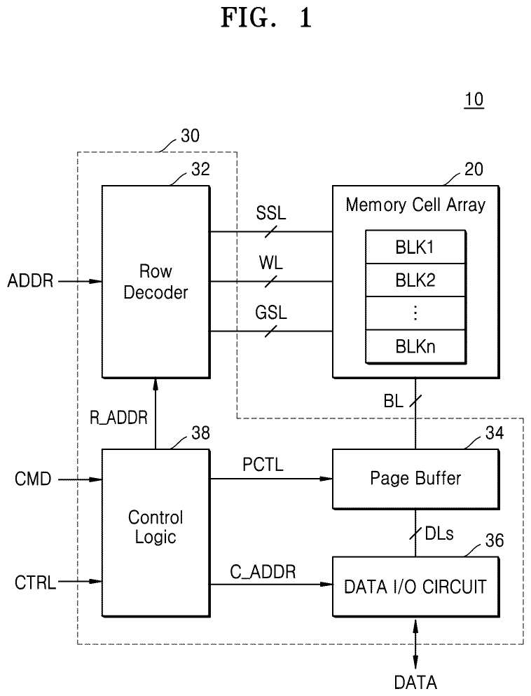

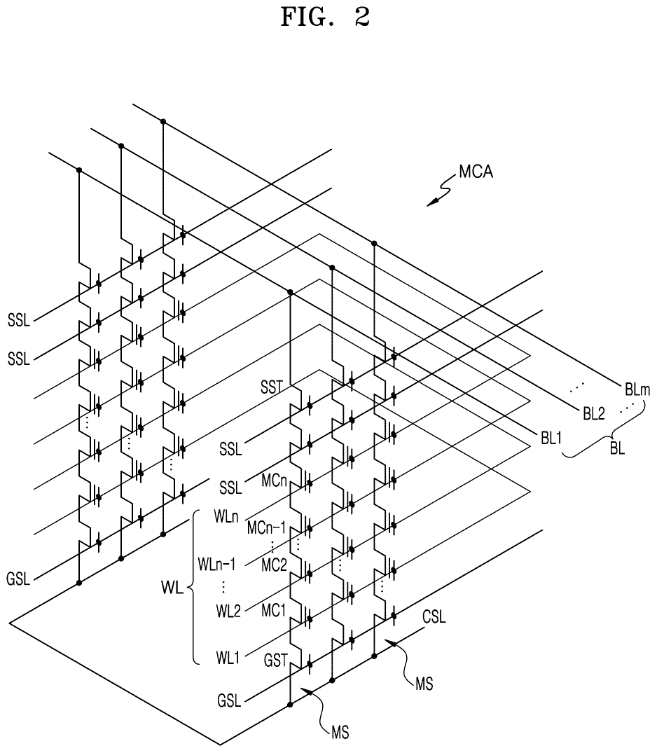

FIG. 1 is a block diagram of a semiconductor device 10 according to embodiments.

Referring to FIG. 1, a semiconductor device 10 may include a memory cell array 20 and a peripheral circuit 30. The memory cell array 20 includes a plurality of memory cell blocks BLK1, BLK2, . . . and BLKn. Each of the plurality of memory cell blocks BLK1, BLK2, . . . , and BLKn may include a plurality of memory cells. The memory cell blocks BLK1, BLK2, . . . , and BLKn may be connected to the peripheral circuit 30 through a bit line BL, a word line WL, a string selection line SSL, and a ground selection line GSL.

The peripheral circuit 30 may include a row decoder 32, a page buffer 34, a data input/output (I/O) circuit 36, and a control logic 38. Although not shown in FIG. 1, the peripheral circuit 30 may further include an input/output interface, a column logic, a voltage generation unit, a pre-decoder, a temperature sensor, a command decoder, an address decoder, an amplification circuit, and the like.

The memory cell array 20 may be connected to the page buffer 34 through the bit line BL, and may be connected to the row decoder 32 through the word line WL, the string selection line SSL, and the ground selection line GSL. In the memory cell array 20, each of the plurality of memory cells included in each of the plurality of memory cell blocks BLK1, BLK2,. and BLKn may be a flash memory cell. The memory cell array 20 may include a three-dimensional memory cell array. The three-dimensional memory cell array may include a plurality of NAND strings, and each NAND string may include a plurality of memory cells connected to a plurality of word lines WL vertically stacked on a substrate.

The peripheral circuit 30 may receive an address ADDR, a command CMD, and a control signal CTRL from the outside of the semiconductor device 10, and may transmit and receive data to and from a device outside the semiconductor device 10.

The row decoder 32 may select at least one of a plurality of memory cell blocks BLK1, BLK2, . . . , and BLKn in response to an address ADDR from the outside, and may select a word line WL, a string selection line SSL, and a ground selection line GSL of the selected memory cell block. The row decoder 32 may transfer a voltage for performing a memory operation to the word line WL of the selected memory cell block.

The page buffer 34 may be connected to the memory cell array 20 through the bit line BL. The page buffer 34 may operate as a write driver during a program operation to apply a voltage according to the data DATA to be stored in the memory cell array 20 to the bit line BL, and may operate as a sense amplifier during a read operation to sense the data stored in the memory cell array 20. The page buffer 34 may operate according to a control signal PCTL provided from the control logic 38.

The data input/output circuit 36 may be connected to the page buffer 34 through data lines DLs. The data I/O circuit 36 may receive data DATA from a memory controller (not shown) during a program operation and provide program data DATA to the page buffer 34 based on a column address C_ADDR provided from the control logic 38. The data I/O circuit 36 may provide read data DATA stored in the page buffer 34 to the memory controller based on the column address C_ADDR provided from the control logic 38 during a read operation.

The data I/O circuit 36 may transmit an input address or instruction to the control logic 38 or the row decoder 32. The peripheral circuit 30 may further include an electrostatic discharge (ESD) circuit and a pull-up/pull-down driver.

The control logic 38 may receive a command CMD and a control signal CTRL from the memory controller (not shown). The control logic 38 may provide a row address R_ADDR to the row decoder 32 and provide a column address C_ADDR to the data I/O circuit 36. The control logic 38 may generate various internal control signals used in the semiconductor device 10 in response to the control signal CTRL. For example, the control logic 38 may adjust a voltage level provided to the word line WL and the bit line BL when performing a memory operation such as a program operation or an erase operation.

FIG. 2 is an equivalent circuit diagram of a memory cell array of a semiconductor device 10 according to embodiments.

Referring to FIG. 2, a memory cell array MCA may include a plurality of memory cell strings MS. The memory cell array MCA may include a plurality of bit lines BL: BL1, BL2, . . . , and BLm, a plurality of word lines WL: WL1, WL2, . . . , WLn-1 and WLn, at least one string selection line SSL, at least one ground selection line GSL, and a common source line CSL. The plurality of memory cell strings MS may be formed between the plurality of bit lines BL: BL1, BL2, . . . , and BLm, and the common source line CSL. FIG. 2 illustrates a case in which each of the plurality of memory cell strings MS includes two string selection lines SSL.

Each of the plurality of memory cell strings MS includes a string selection transistor SST, a ground selection transistor GST, and a plurality of memory cell transistors MC1, MC2 . . . , MCn-1 and MCn. A drain region of the string selection transistor SST may be connected to the bit lines BL: BL1, BL2, and BLm, and a source region of the ground selection transistor GST may be connected to the common source line CSL. The common source line CSL may be a region to which source regions of the plurality of ground selection transistors GST are commonly connected.

The string selection transistor SST may be connected to the string selection line SSL, and the ground selection transistor GST may be connected to the ground selection line GSL. Each of a plurality of memory cell transistors MC1, MC2, . . . , MCn-1 and MCn may be connected to a plurality of word lines WL: WL1, WL2, . . . , WLn-1 and WLn.

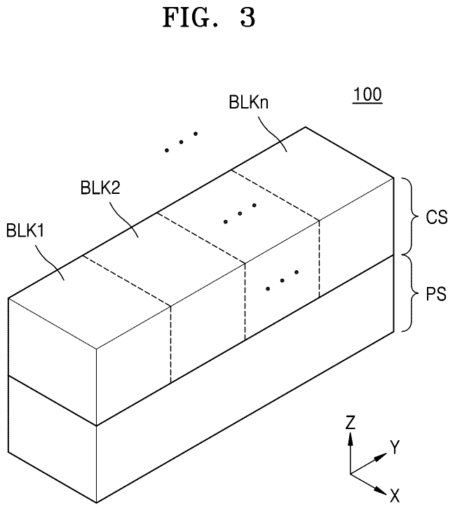

FIG. 3 is a perspective view illustrating a representative configuration of a semiconductor device 100 according to embodiments.

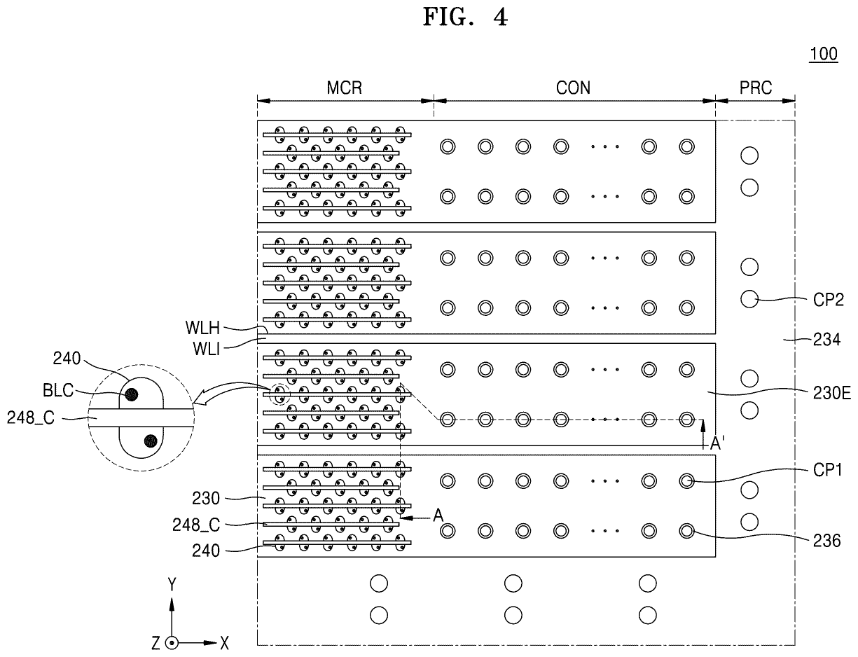

FIG. 4 is a plan view illustrating the semiconductor device 100 of FIG. 3 according to embodiments.

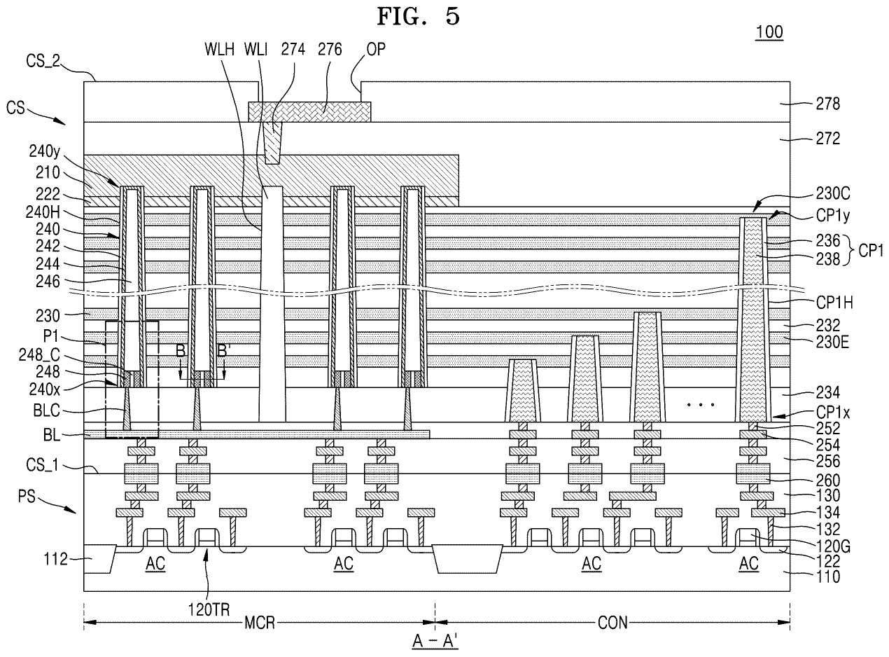

FIG. 5 is a cross-sectional view taken along line A-A′ of FIG. 4.

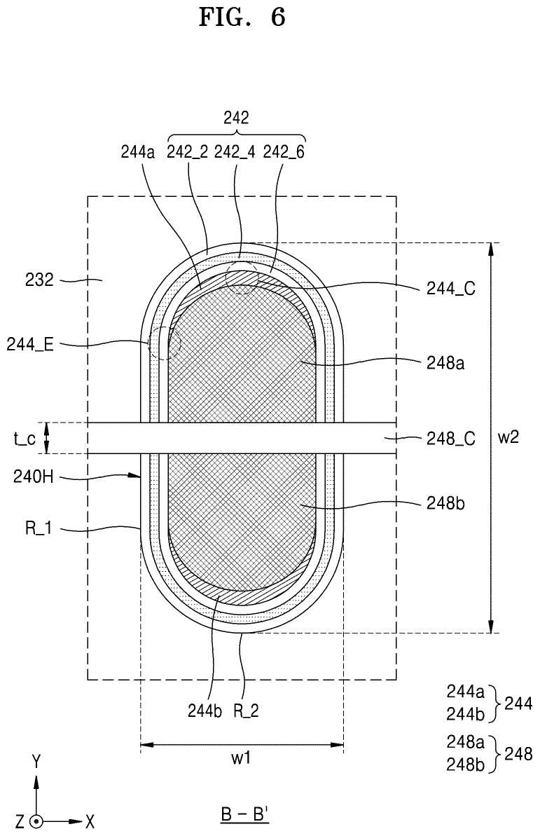

FIG. 6 is a schematic plan view at a vertical level taken along line B-B′ of FIG. 5.

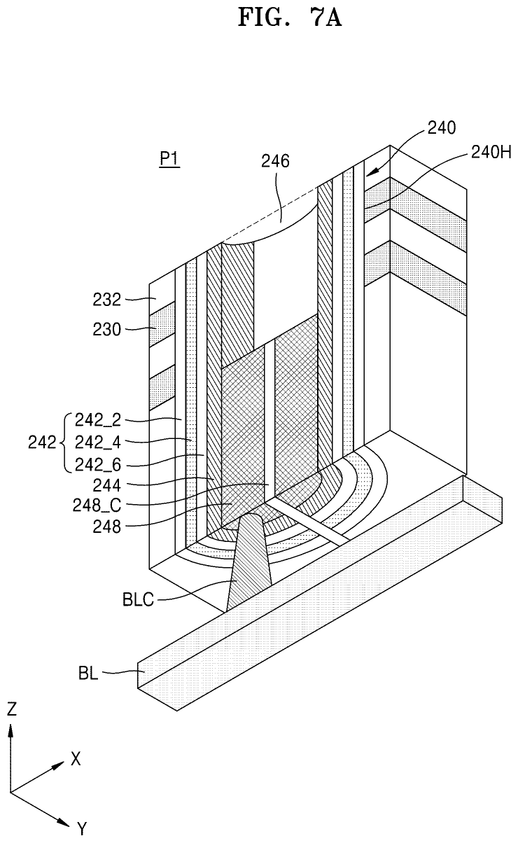

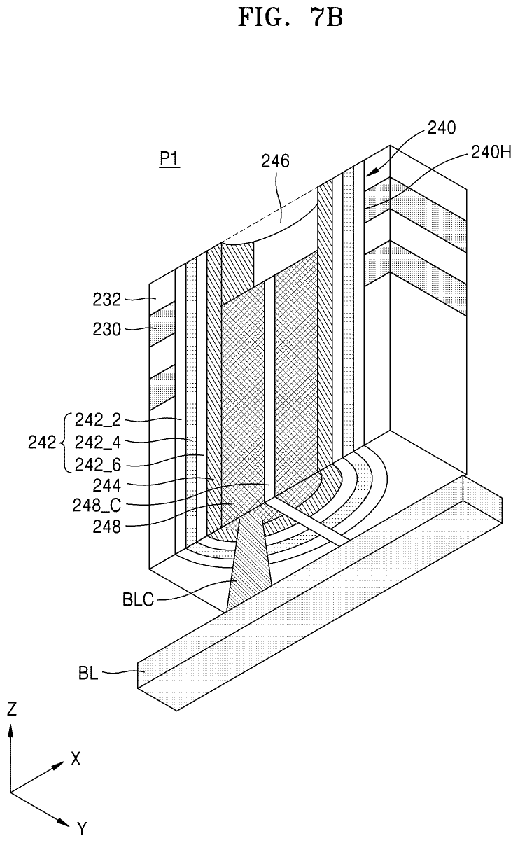

FIGS. 7A and 7B are schematic perspective views of portions indicated by “P1” in FIG. 5, respectively.

Referring to FIGS. 3 to 7B, a semiconductor device 100 includes a cell structure CS and a peripheral circuit structure PS, which overlap each other in a vertical direction (Z direction). The cell structure CS may include the memory cell array 20 described with reference to FIG. 1, and the peripheral circuit structure PS may include the peripheral circuit 30 described with reference to FIG. 1.

The cell structure CS may include a plurality of memory cell blocks BLK1, BLK2, . . . , and BLKn. Each of the plurality of memory cell blocks BLK1, BLK2, . . . , and BLKn may include memory cells, which are three-dimensionally arranged.

The peripheral circuit structure PS may include peripheral circuit transistors 120TR arranged on a substrate 110. An active region AC may be defined on the substrate 110 by a device isolation layer 112, and the plurality of peripheral circuit transistors 120TR may be formed on the active region AC. Each of the plurality of peripheral circuit transistors 120TR may include a peripheral circuit gate 120G and a source/drain region 122 arranged on both sides of the peripheral circuit gate 120G on a portion of the substrate 110.

The substrate 110 may include a semiconductor material, for example, a group IV semiconductor, a group III-V compound semiconductor, or a group II-VI oxide semiconductor. For example, the group IV semiconductor may include silicon (Si), germanium (Ge), or silicon-germanium. The substrate 110 may be provided as a bulk wafer or an epitaxial layer. In another embodiment, the substrate 110 may include a silicon-on-insulator (SOI) substrate or a germanium-on-insulator (GeOI) substrate.

A plurality of peripheral circuit contacts 132 and a plurality of peripheral circuit wiring layers 134 may be arranged on a top surface of the substrate 110. An interlayer insulating layer 130 covering the peripheral circuit transistors 120TR, the plurality of peripheral circuit contacts 132, and the plurality of peripheral circuit wiring layers 134 may be arranged on the substrate 110. The plurality of peripheral circuit wiring layers 134 may have a multilayer structure including a plurality of metal layers arranged at different vertical levels. Connection pads 260 may be arranged on the interlayer insulating layer 130, and the peripheral circuit structure PS and the cell structure CS may be electrically connected and bonded to each other by the connection pads 260.

The cell structure CS may include a cell region MCR, a connection region CON, and a peripheral circuit connection region PCR. The cell region MCR may be a region in which a memory cell block BLK including a plurality of memory cell strings extending in the vertical direction (Z direction) is arranged. A common source layer 210, a plurality of gate electrodes 230, and a channel structure 240 extending in the vertical direction (Z direction) through the plurality of gate electrodes 230 and connected to the common source layer 210 may be arranged in the cell region MCR. A plurality of extension portions 230E connected to the plurality of gate electrodes 230 and a plurality of cell plugs CP1 respectively electrically connected to the plurality of extension portions 230E may be arranged in the connection region CON. A peripheral plug CP2 extending in the vertical direction (Z direction) and electrically connected to the peripheral circuit wiring layer 134 may be arranged in the peripheral circuit connection region PCR.

The cell structure CS may include a first surface CS_1 connected to the peripheral circuit structure PS and a second surface CS_2 opposite to the first surface CS_1. In the drawings, the first surface CS_1 of the cell structure CS is arranged at a lower side of the cell structure CS, and the second surface CS_2 of the cell structure CS is arranged at an upper side of the cell structure CS. Here, for convenience, as shown in the drawing, a feature of being arranged close to the first surface CS_1 of the cell structure CS is referred to as being arranged at a lower vertical level, and a feature of being arranged close to the second surface CS_2 of the cell structure CS is referred to as being arranged at a higher vertical level.

The plurality of gate electrodes 230 may be arranged to be spaced apart from each other in the vertical direction (Z direction) in the cell region MCR, and the plurality of gate electrodes 230 may be alternately arranged with a plurality of mold insulating layers 232. The plurality of gate electrodes 230 may extend to the connection region CON, and portions of the plurality of gate electrodes 230 arranged in the connection region CON may be referred to as extension portions 230E. The extension portions 230E arranged to be spaced apart from each other in the vertical direction (Z direction) may have the same width in the first horizontal direction (X direction).

In embodiments, the plurality of gate electrodes 230 may include a metal such as tungsten, nickel, cobalt, tantalum, etc., a metal silicide such as tungsten silicide, nickel silicide, cobalt silicide, tantalum silicide, etc., doped polysilicon, or a combination thereof.

In embodiments, the plurality of gate electrodes 230 may correspond to ground selection lines GSL1 to GSL3, word lines WL1 to WL8, and at least one string selection line SSL1 to SSL3 constituting the memory cell strings MCS11 to MCS33 (see FIG. 2). For example, the uppermost gate electrode 230 may function as the ground selection lines GSL1 to GSL3, the lowermost two gate electrodes 230 may function as the string selection lines SSL1 to SSL3, and the remaining gate electrodes 230 may function as the word lines WL1 to WL8. Accordingly, the memory cell strings MCS11 to MCS33 connected in series with the ground selection transistor GST, the string selection transistor SST, and the memory cell transistors MCT1 to MCT8 therebetween may be provided. In some embodiments, at least one of the plurality of gate electrodes 230 may function as a dummy word line, but is not limited thereto.

A stack isolation insulating layer WLI may be arranged in a stack isolation opening WLH penetrating the plurality of gate electrodes 230 and the plurality of mold insulating layers 232 and extending in the vertical direction (Z direction). The stack isolation insulating layer WLI may have a top surface arranged at a higher vertical level than the uppermost gate electrode 230, and may protrude upward with respect to the uppermost gate electrode 230. In some embodiments, the plurality of gate electrodes 230 arranged between a pair of the stack isolation openings WLH may constitute one block.

The channel structure 240 may be arranged in a channel hole 240H extending in the vertical direction (Z direction) through the plurality of gate electrodes 230 and the plurality of mold insulating layers 232. The channel structure 240 may include a gate insulating layer 242, a channel layer 244, a buried insulating layer 246, and a drain region 248. The gate insulating layer 242 may be arranged on an inner wall of the channel hole 240H, the channel layer 244 may be arranged on an inner wall of the gate insulating layer 242, and the buried insulating layer 246 and the drain region 248 may be arranged on an inner wall of the channel layer 244. The buried insulating layer 246 may cover a portion (e.g., an upper portion) of the inner wall of the channel layer 244, and the drain region 248 may cover some of the remaining portions (e.g., a lower portion) of the inner wall of the channel layer 244.

In embodiments, as illustrated in FIG. 6, the channel hole 240H may include a pair of first regions R_1 facing each other in the first horizontal direction (X direction) and a pair of second regions R_2 facing each other in the second horizontal direction (Y direction). The channel hole 240H may have a first width w1 in the first horizontal direction (X direction), and a second width w2 in the second horizontal direction (Y direction), and the second width w2 may be greater than the first width w1.

In some embodiments, the pair of first regions R_1 of the channel hole 240H may have a first curvature, the pair of second regions R_2 may have a second curvature, and the second curvature may be greater than the first curvature. In some embodiments, the first curvature may be zero. In other words, the pair of first regions R_1 of the channel hole 240H each may have a flat inner wall, and the pair of second regions R_2 of the channel hole 240H each may have a curved surface. In some other embodiments, the second curvature may be less than the first curvature. In some other embodiments, the second curvature may be zero. In other words, the pair of first regions R_1 of the channel hole 240H each may have a curved inner wall, and the pair of second regions R_2 of the channel hole 240H each may have a flat inner wall.

In embodiments, the gate insulating layer 242 may have a structure including a blocking dielectric layer 242_2, a charge storage layer 242_4, and a tunneling dielectric layer 242_6, which are arranged sequentially on the inner wall of the channel hole 240H. Relative thicknesses of the blocking dielectric layer 242_2, the charge storage layer 242_4, and the tunneling dielectric layer 242_6 are not limited thereto, as illustrated, and may be variously modified.

The blocking dielectric layer 242_2 may include silicon oxide, silicon nitride, or a metal oxide having a higher dielectric constant than silicon oxide. The metal oxide may include hafnium oxide, aluminum oxide, zirconium oxide, tantalum oxide, or a combination thereof. The charge storage layer 242_4 is a region in which electrons passing through the tunneling dielectric layer from the channel layer 244 may be stored, and may include silicon nitride, boron nitride, silicon boron nitride, or polysilicon doped with impurities. In some embodiments, the charge storage layer 242_4 may include a ferroelectric dielectric material. In this case, the charge storage layer 242_4 may include a metal oxide having ferroelectric material properties. For example, the charge storage layer 242_4 may include a ferroelectric material capable of storing data by hysteresis behavior by the voltage applied to the charge storage layer 242_4. In embodiments, the charge storage layer 242_4 may include at least one of hafnium oxide, zirconium oxide, and hafnium zirconium oxide. The tunneling dielectric layer 242_6 may include silicon oxide, hafnium oxide, aluminum oxide, zirconium oxide, tantalum oxide, or the like.

In embodiments, as illustrated in FIG. 6, the channel layer 244 may be arranged on the inner wall of the gate insulating layer 242 to cover a portion of the inner wall of the gate insulating layer 242, and may not cover the other portions of the inner wall of the gate insulating layer 242. The channel layer 244 may include a plurality of channel patterns. For example, the channel layer 244 may include a first channel pattern 244a and a second channel pattern 244b. The first channel pattern 244a and the second channel pattern 244b may be arranged on the pair of second regions R_2 of the channel hole 240H, respectively. The first channel pattern 244a and the second channel pattern 244b may be arranged to be spaced apart from each other in the second horizontal direction (Y direction), and may be electrically separated from each other. The first channel pattern 244a and the second channel pattern 244b may be electrically connected to different bit lines BL, respectively, and may operate independently.

In some embodiments, the first channel pattern 244a and the second channel pattern 244b may each have a shape in which the thickness decreases from the central portion 244_C toward the edge portion 244_E on the layout. In some embodiments, the central portion 244_C of each of the first channel pattern 244a and the second channel pattern 244b may include a portion having a relatively greater curvature than the edge portion 244_E of each of the first channel pattern 244a and the second channel pattern 244b. For example, the first channel pattern 244a and the second channel pattern 244b each may have a curved shape in which both sidewalls are concave, and may have, as a whole, a closed curve shape in which curves formed by both sidewalls contact each other. In other words, the first channel pattern 244a and the second channel pattern 244b may have a closed curve shape with one side convex and the other side concave, formed by cutting a portion of an elliptical shape on the layout.

The shapes of the first channel pattern 244a and the second channel pattern 244b may be shapes caused by a difference between a deposition amount per hour on the first region R_1 and a deposition amount per hour on the second region R_2 in a process of depositing the preliminary channel layer in a manufacturing process, and a process of isotropically etching the preliminary channel layer. A detailed manufacturing process of the first channel pattern 244a and the second channel pattern 244b will be described later.

In embodiments, as illustrated in FIG. 6, the drain region 248 may include a plurality of drain patterns. For example, the drain region 248 may include a first drain pattern 248a and a second drain pattern 248b. The first drain pattern 248a and the second drain pattern 248b may cover inner walls of the first channel pattern 244a and the second channel pattern 244b, and may cover a portion of the inner wall of the gate insulating layer 242 that is not covered by the first channel pattern 244a and the second channel pattern 244b.

A drain region cut 248_C may be arranged between the first drain pattern 248a and the second drain pattern 248b. The drain region cut 248_C may include an insulating material such as silicon oxide, silicon nitride, or a combination thereof. The drain region cut 248_C may electrically separate the first drain pattern 248a and the second drain pattern 248b from each other. The first drain pattern 248a and the second drain pattern 248b may be spaced apart from each other in the second horizontal direction (Y direction) with the drain region cut 248_C therebetween.

The drain region cut 248_C may be arranged between the first channel pattern 244a and the second channel pattern 244b. For example, the first drain pattern 248a may be arranged between the first channel pattern 244a and one sidewall of the drain region cut 248_C, and the second drain pattern 248b may be arranged between the second channel pattern 244b and the other sidewall of the drain region cut 248_C.

In some embodiments, as illustrated in FIG. 4, the drain region cut 248_C may extend long in the first horizontal direction (X direction) through the gate insulating layer 242. However, in some other embodiments, although not illustrated, the drain region cut 248_C may extend short in the first horizontal direction (X direction) to penetrate one, two, or three channel structures 240. The number of channel structures 240 through which the drain region cut 248_C passes is not limited as illustrated. Alternatively, the drain region cut 248_C may extend shorter in the first horizontal direction (X direction) to penetrate only the drain region 248 without penetrating the gate insulating layer 242. The thickness t_c of the drain region cut 248_C in the second horizontal direction (Y direction) is not limited, but may be formed to be less than or equal to the minimum separation distance between the first channel pattern 244a and the second channel pattern 244b (e.g., a separation distance on the tunneling dielectric layer 242_6 between the first channel pattern 244a and the second channel pattern 244b). In some embodiments, the thickness t_c of the drain region cut 248_C in the second horizontal direction (Y direction) may be within about 20 nanometers to about 80 nanometers.

As a comparative example, a semiconductor device that includes a hole cut that penetrates a channel structure and separates a channel layer into two channel patterns has a relatively thick hole cut in the horizontal direction as long as the hole cut is formed in a long vertical length to penetrate the channel structure. As a result, there is a problem in that the size of the channel structure on the layout should be relatively large. Since the drain region cut 248_C in embodiments of the inventive concept is formed to penetrate the drain region 248 of the channel structure 240 and thus has a shorter vertical length than the hole cut, the thickness of the drain region cut 248_C in the horizontal direction may be relatively thin, and the size of the channel structure 240 on the layout may be formed relatively small, thereby providing a semiconductor device with improved integration.

In some embodiments, as illustrated in FIGS. 7A and 7B, the drain region cut 248_C may extend in the vertical direction (Z direction), and the top surface of the drain region cut 248_C may be in contact with the bottom surface of the buried insulating layer 246. The drain region 248 and the drain region cut 248_C may be located under the buried insulation layer 246.

The buried insulating layer 246 may overlap the plurality of gate electrodes 230 in the first horizontal direction (X direction) and the second horizontal direction (Y direction), and the drain region 248 may not overlap the plurality of gate electrodes 230 in the first horizontal direction (X direction) and the second horizontal direction (Y direction). The drain region 248 may overlap only the mold insulating layer 232 located at the lowermost end in the first horizontal direction (X direction) and the second horizontal direction (Y direction). In some other embodiments, the buried insulating layer 246 may overlap some of the plurality of gate electrodes 230 in the first horizontal direction (X direction) and the second horizontal direction (Y direction), and the drain region 248 may overlap some others of the plurality of gate electrodes 230 in the first horizontal direction (X direction) and the second horizontal direction (Y direction).

The channel structure 240 may include a first end 240x arranged close to the peripheral circuit structure PS and a second end 240y opposite to the first end 240x. In embodiments, the channel structure 240 may have an inclined sidewall such that the width of the first end 240x is greater than the width of the second end 240y.

The drain region 248 electrically connected to the channel layer 244 may be arranged at the first end 240x of the channel structure 240. The drain region 248 may be connected to a bit line contact BLC, and the channel layer 244 may be electrically connected to the bit line BL through the drain region 248 and the bit line contact BLC. Specifically, each of the first drain pattern 248a and the second drain pattern 248b may be connected to the bit line contact BLC, and each of the first channel pattern 244a and the second channel pattern 244b may be connected to the bit line BL through the first drain pattern 248a, the second drain pattern 248b, and the bit line contact BLC. The bit line contact BLC and the bit line BL to which the first drain pattern 248a and the first channel pattern 244a are electrically connected may be different from the bit line contact BLC and the bit line BL to which the second drain pattern 248b and the second channel pattern 244b are electrically connected. Accordingly, one channel structure 240 may be connected to two bit line contacts BLC to be electrically connected to the two bit lines BL, and one channel structure 240 may constitute two memory cell strings MS shown in FIG. 2.

In the second end 240y of the channel structure 240, the top surface of the channel layer 244 may not be covered by the gate insulating layer 242, and a common source layer 210 may be connected to the top surface of the channel layer 244.

An etching stop layer 222 may be arranged on the uppermost gate electrode 230, and the etching stop layer 222 may include polysilicon. In some embodiments, the etching stop layer 222 may be omitted.

The common source layer 210 may be conformally formed on the etching stop layer 222 to be connected to the second end 240y of the channel structure 240 and to cover the top surface of the stack isolation insulating layer WLI. When viewed in a plan view, the common source layer 210 may be arranged on the entire region of the cell region MCR.

In embodiments, the common source layer 210 may include at least one of silicon (Si), germanium (Ge), silicon germanium (SiGe), gallium arsenide (GaAs), indium gallium arsenide (InGaAs), aluminum gallium arsenide (AlGaAs), or a mixture thereof. In addition, the common source layer 210 may include a semiconductor doped with n-type impurities. In addition, the common source layer 210 may have a crystal structure including at least one selected from single crystals, amorphous, and polycrystalline. In some examples, the common source layer 210 may include polysilicon doped with n-type impurities.

A connection via 252, a connection wiring layer 254, and an interlayer insulating layer 256 surrounding the connection via 252 and the connection wiring layer 254 may be arranged between a stack cover insulating layer 234 and the peripheral circuit structure PS. The connection via 252 and the connection wiring layer 254 may be formed in multiple layers to be arranged at a plurality of vertical levels, and the bit lines BL, the cell plugs CP1, and the peripheral plugs CP2 may be electrically connected to the peripheral circuit structure PS through the connection pads 260.

The plurality of gate electrodes 230 may extend in a horizontal direction on the cell region MCR and the connection region CON. The plurality of gate electrodes 230 arranged on the connection region CON are referred to as gate extension portions 230E. A plurality of gate extension portions 230E may overlap each other in a vertical direction on the connection region CON. For example, the plurality of gate extension portions 230E arranged at different vertical levels on the connection region CON may have the same width in the horizontal direction.

The cell plug CP1 may be arranged in a cell plug hole CP1H extending in a vertical direction (Z direction) through the stack cover insulating layer 234, the mold insulating layer 232, and the gate extension portions 230E on the connection region CON. The cell plug CP1 may include an insulating liner 236 and a conductive plug 238. The insulating liner 236 may be arranged on an inner wall of the cell plug hole CP1H, and a conductive plug 238 may be arranged on an inner wall of the insulating liner 236.

A plurality of conductive plugs 238 may have heights that vary in the vertical direction (Z direction). In embodiments, each of the plurality of conductive plugs 238 has a first end CP1x and a second end CP1y, and the first ends CP1x of the plurality of conductive plugs 238 may all be arranged at the same vertical level, and may also be arranged at the same vertical level as the top surface of the stack cover insulating layer 234. The second ends CP1y of the plurality of conductive plugs 238 may be arranged at different vertical levels, and for example, the second ends CP1y of the plurality of conductive plugs 238 may be placed on corresponding gate contact surfaces 230C, respectively.

In embodiments, a bottom surface of each of the plurality of conductive plugs 238 may be in contact with a gate contact surface 230C, and accordingly, one conductive plug 238 may be electrically connected to the corresponding gate extension portion 230E through the gate contact surface 230C.

In embodiments, the bottom surface of one conductive plug 238 may be electrically connected to the corresponding gate extension portion 230E, while the sidewall of one conductive plug 238 may not be electrically connected to the corresponding gate extension portion 230E by the insulating liner 236 arranged between the conductive plug 238 and the plurality of gate electrodes 230.

In embodiments, the insulating liner 236 may include silicon oxide. In embodiments, the conductive plugs 238 may include a metal such as tungsten, nickel, cobalt, tantalum, etc., a metal silicide such as tungsten silicide, nickel silicide, cobalt silicide, tantalum silicide, etc., doped polysilicon, or a combination thereof.

FIG. 5 illustrates a stair-free contact structure forming a cell plug hole CP1H passing through a plurality of gate electrodes 230 and forming an insulating liner 236 on a sidewall of the cell plug hole CP1H, but embodiments according to the inventive concept are not limited thereto, and a structure in which a conductive plug 238 is landed on a stair-shaped pad part connected to a plurality of gate electrodes 230 in the connection region CON may be also included in the inventive concept.

An upper insulating layer 272 may be arranged on the common source layer 210. The upper insulating layer 272 may have a flat top surface over the entire cell region MCR and the entire connection region CON. A common source contact 274 penetrating the upper insulating layer 272 and connected to the common source layer 210 may be arranged, and a rear wiring layer 276 electrically connected to the common source contact 274 may be arranged on the upper insulating layer 272.

A passivation layer 278 covering the rear wiring layer 276 may be arranged on the upper insulation layer 272. The passivation layer 278 may include an opening OP exposing a top surface of the rear wiring layer 276.

Although not shown, dummy channels (not shown) extending in the vertical direction (Z direction) through the plurality of gate electrodes 230 and the plurality of mold insulating layers 232 in the connection region CON may be further formed. The dummy channels may be formed to prevent leaning or bending of the gate electrodes 230 in a manufacturing process of the semiconductor device 100 and to secure structural stability.

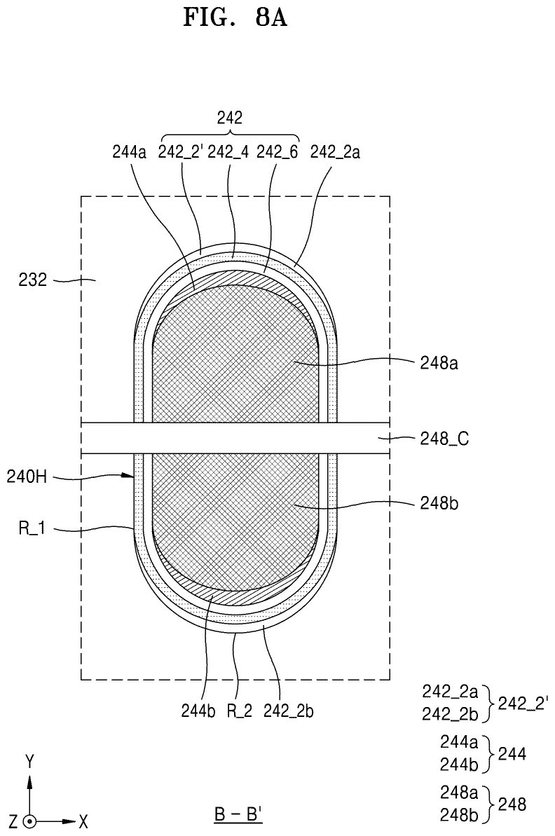

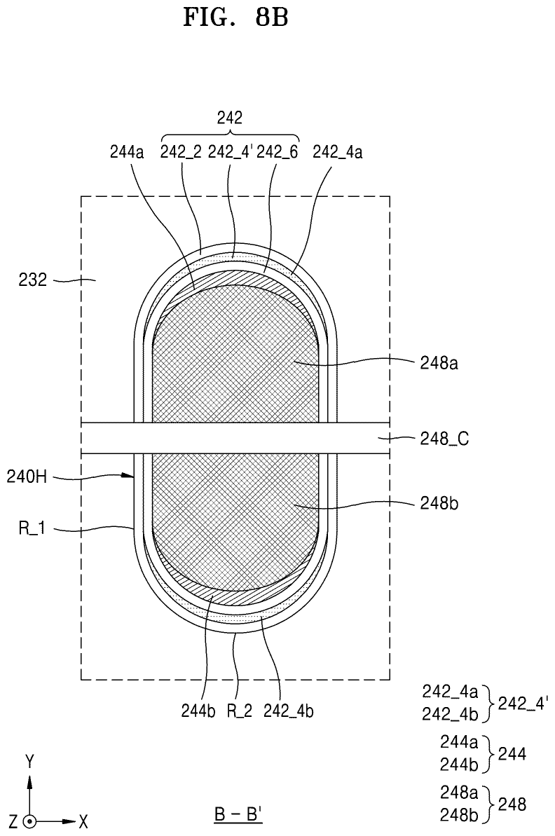

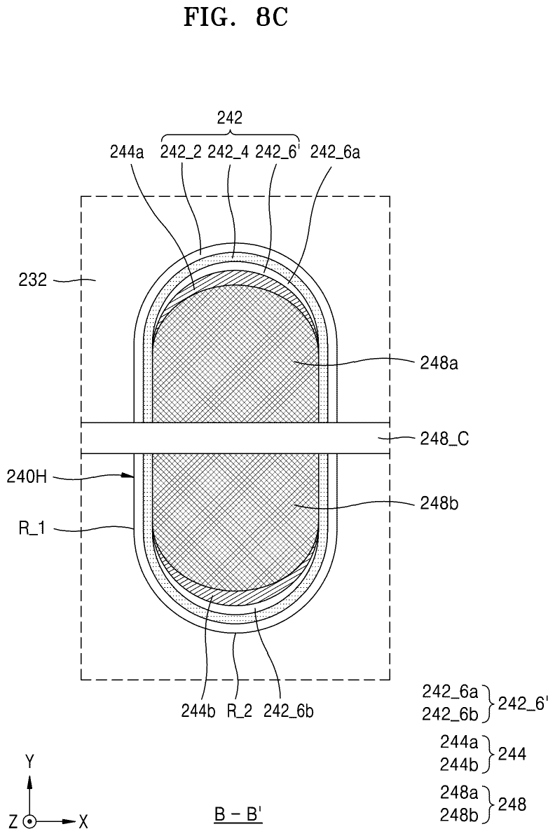

FIGS. 8A to 8C are schematic plan views for describing another embodiment at the vertical level taken along line B-B′ of FIG. 5, respectively.

Referring to FIG. 8A, a blocking dielectric layer 242_2′ may be arranged on the inner wall of the channel hole 240H to cover a portion of the inner wall of the channel hole 240H and not to cover a portion of the other remaining portions of the inner wall of the channel hole 240H. The blocking dielectric layer 242_2′ may include a plurality of blocking dielectric patterns. For example, the blocking dielectric layer 242_2′ may include a first blocking dielectric pattern 242_2a and a second blocking dielectric pattern 242_2b. The first blocking dielectric pattern 242_2a and the second blocking dielectric pattern 242_2b may be arranged on a pair of second regions R_2 of the channel hole 240H, respectively. The first blocking dielectric pattern 242_2a and the second blocking dielectric pattern 242_2b may be arranged to be spaced apart from each other in the second horizontal direction (Y direction).

In some embodiments, the first blocking dielectric pattern 242_2a and the second blocking dielectric pattern 242_2b may have a thickness that decreases from the center toward the edge on the layout. The shapes of the first blocking dielectric pattern 242_2a and the second blocking dielectric pattern 242_2b may be shapes caused by a difference between a deposition amount per hour on the first region R_1 and a deposition amount per hour on the second region R_2 in a process of depositing the preliminary blocking dielectric layer in a manufacturing process, and a process of isotropically etching the preliminary blocking dielectric layer.

Referring to FIG. 8B, a charge storage layer 242_4′ may be arranged on the inner wall of the blocking dielectric layer 242_2 to cover a portion of the inner wall of the blocking dielectric layer 242_2 and not to cover a portion of the other remaining portions of the inner wall of the blocking dielectric layer 242_2. The charge storage layer 242_4′ may include a plurality of charge storage patterns. For example, the charge storage layer 242_4′ may include a first charge storage pattern 242_4a and a second charge storage pattern 242_4b. The first charge storage pattern 242_4a and the second charge storage pattern 242_4b may be arranged on the pair of second regions R_2 of the channel hole 240H, respectively. The first charge storage pattern 242_4a and the second charge storage pattern 242_4b may be arranged to be spaced apart from each other in the second horizontal direction (Y direction).

In some embodiments, the first charge storage pattern 242_4a and the second charge storage pattern 242_4b may have a thickness that decreases from the center toward the edge on the layout. The shapes of the first charge storage pattern 242_4a and the second charge storage pattern 242_4b may be shapes caused by a difference between a deposition amount per hour on the first region R_1 and a deposition amount per hour on the second region R_2 in a process of depositing the preliminary charge storage layer in a manufacturing process, and a process of isotropically etching the preliminary charge storage layer.

Referring to FIG. 8C, a tunneling dielectric layer 242_6′ may be arranged on the inner wall of the charge storage layer 242_4 to cover a portion of the inner wall of the charge storage layer 242_4 and not to cover a portion of the other remaining portions of the inner wall of the charge storage layer 242_4. The tunneling dielectric layer 242_6′ may include a plurality of tunneling dielectric patterns. For example, the tunneling dielectric layer 242_6′ may include a first tunneling dielectric pattern 242_6a and a second tunneling dielectric pattern 242_6b. The first tunneling dielectric pattern 242_6a and the second tunneling dielectric pattern 242_6b may be arranged on a pair of second regions R_2 of the channel hole 240H, respectively. The first tunneling dielectric pattern 242_6a and the second tunneling dielectric pattern 242_6b may be arranged to be spaced apart from each other in the second horizontal direction (Y direction).

In some embodiments, the first tunneling dielectric pattern 242_6a and the second tunneling dielectric pattern 242_6b may have a thickness that decreases from the center toward the edge on the layout. The shapes of the first tunneling dielectric pattern 242_6a and the second tunneling dielectric pattern 242_6b may be shapes caused by a difference between a deposition amount per hour on the first region R_1 and a deposition amount per hour on the second region R_2 in a process of depositing the preliminary tunneling dielectric layer in a manufacturing process, and a process of isotropically etching the preliminary tunneling dielectric layer.

Although the cases of including the blocking dielectric layer 242_2′, the charge storage layer 242_4′, and the tunneling dielectric layer 242_6′ have been illustrated in FIGS. 8A to 8C, respectively, embodiments are not limited thereto, and may include a combination of the blocking dielectric layer 242_2′, the charge storage layer 242_4′, and the tunneling dielectric layer 242_6′ shown in FIGS. 8A to 8C.

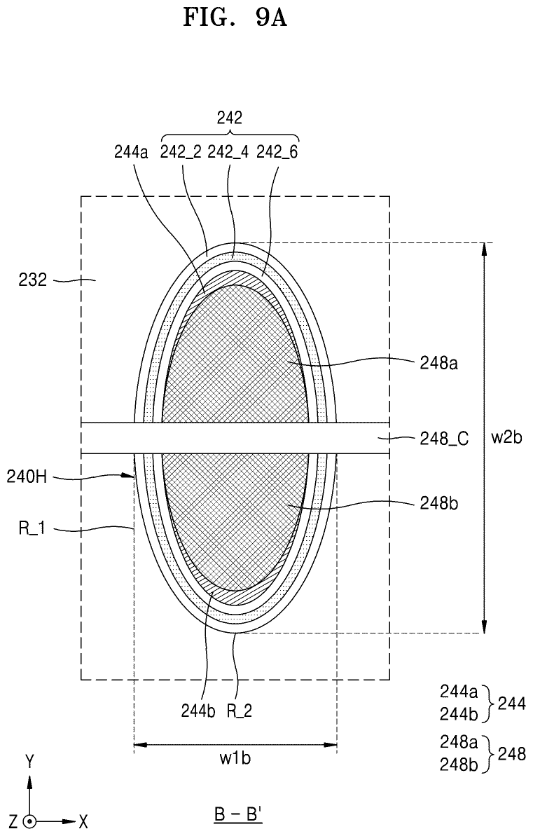

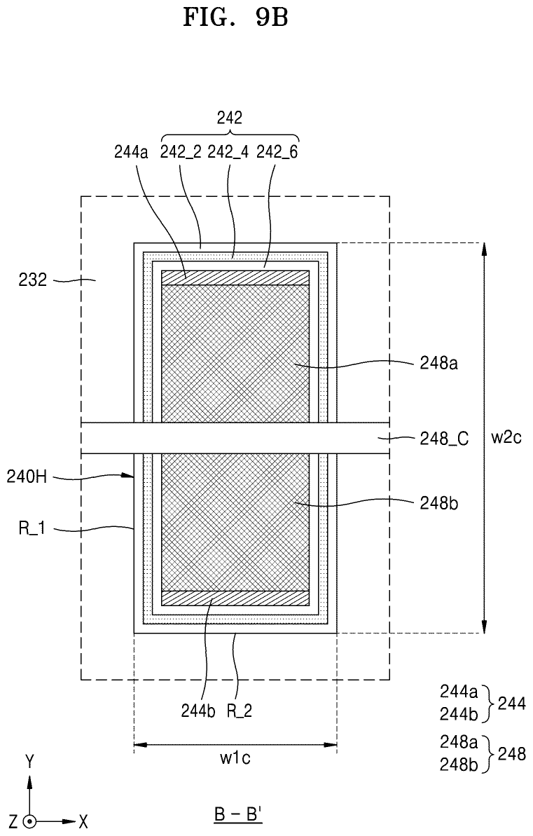

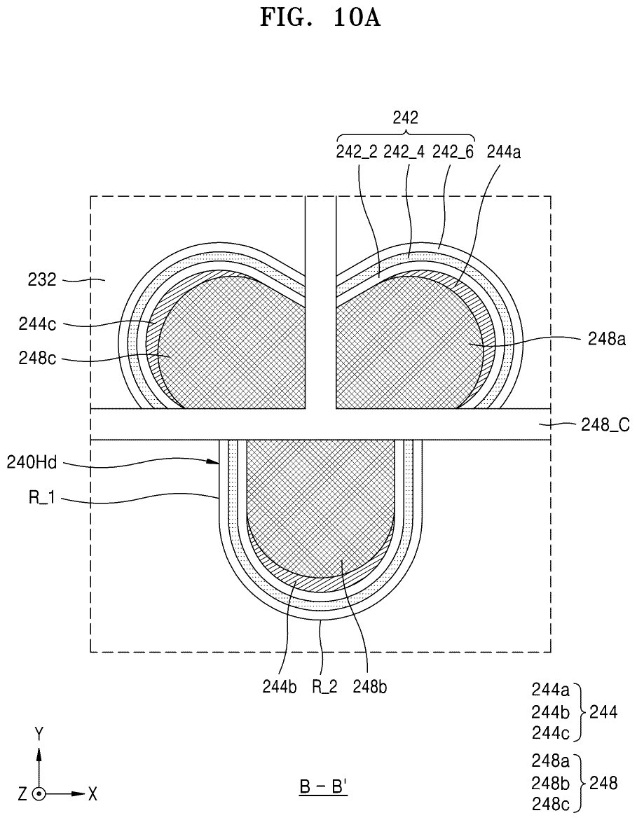

FIGS. 9A and 9B are schematic plan views for describing another embodiment at the vertical level taken along line B-B′ of FIG. 5, respectively.

Referring to FIG. 9A, a channel hole 240Hb may include a pair of first regions R_1 facing each other in the first horizontal direction (X direction) and a pair of second regions R_2 facing each other in the second horizontal direction (Y direction). The channel hole 240Hb may have a first width w1b in the first horizontal direction (X direction), and a second width w2b in the second horizontal direction (Y direction), and the second width w2b may be greater than the first width w1b.

In some embodiments, the pair of first regions R_1 of the channel hole 240Hb may have a first curvature, the pair of second regions R_2 may have a second curvature, and the second curvature may be greater than the first curvature. The channel hole 240Hb may be formed in an oval shape elongated in the second horizontal direction (Y direction) on the layout.

Referring to FIG. 9B, a channel hole 240Hc may include a pair of first regions R_1 facing each other in the first horizontal direction (X direction) and a pair of second regions R_2 facing each other in the second horizontal direction (Y direction). The channel hole 240Hc may have a first width w1c in the first horizontal direction (X direction), and a second width w2c in the second horizontal direction (Y direction), and the second width w2c may be greater than the first width w1c.

In some embodiments, the channel hole 240Hc may be formed in a rectangular shape elongated in the second horizontal direction (Y direction) on the layout.

However, the shape of the channel hole of the inventive concept is not limited to the illustration, and various shapes having a second width in the second horizontal direction (Y direction) greater than the first width in the first horizontal direction (X direction) may be employed.

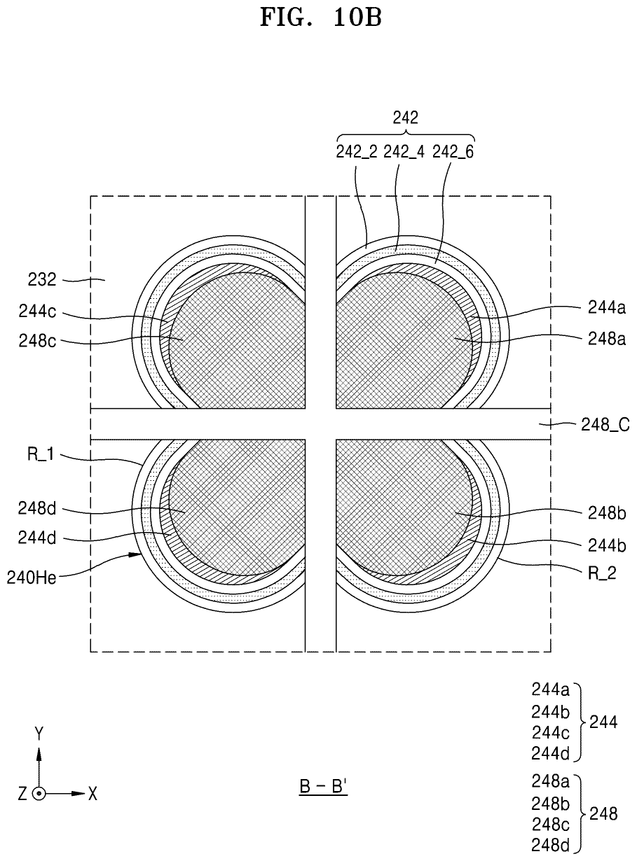

FIGS. 10A and 10B are schematic plan views illustrating semiconductor devices according to other embodiments, respectively.

Referring to FIG. 10A, a channel hole 240Hd may include a plurality of first regions R_1 having a first curvature and a plurality of second regions R_2 having a second curvature greater than the first curvature. In some embodiments, the first curvature may be zero. In other words, the plurality of first regions R_1 of the channel hole 240Hd each may have a flat inner wall, and the plurality of second regions R_2 of the channel hole 240Hd each may have an inner wall including a curved surface.

A channel layer 244 may include a plurality of channel patterns. For example, the channel layer 244 may include a first channel pattern 244a, a second channel pattern 244b, and a third channel pattern 244c. The first channel pattern 244a, the second channel pattern 244b, and the third channel pattern 244c may be arranged on a plurality of second regions R_2 of the channel hole 240Hd, respectively. The first channel pattern 244a, the second channel pattern 244b, and the third channel pattern 244c may be arranged to be spaced apart from each other, and may be electrically separated from each other. The first channel pattern 244a, the second channel pattern 244b, and the third channel pattern 244c may be electrically connected to different bit lines BL, respectively, and may operate independently.

Referring to FIG. 10B, a channel hole 240He may include a plurality of first regions R_1 having a first curvature and a plurality of second regions R_2 having a second curvature greater than the first curvature. In some embodiments, the first curvature may be zero. In other words, the plurality of first regions R_1 of the channel hole 240He each may have a flat inner wall, and the plurality of second regions R_2 of the channel hole 240He each may have an inner wall including a curved surface.

A channel layer 244 may include a plurality of channel patterns. For example, the channel layer 244 may include a first channel pattern 244a, a second channel pattern 244b, a third channel pattern 244c, and a fourth channel pattern 244d. The first channel pattern 244a, the second channel pattern 244b, the third channel pattern 244c, and the fourth channel pattern 244d may be arranged on a plurality of second regions R_2 of the channel hole 240He, respectively. The first channel pattern 244a, the second channel pattern 244b, the third channel pattern 244c, and the fourth channel pattern 244d may be arranged to be spaced apart from each other, and may be electrically separated from each other. The first channel pattern 244a, the second channel pattern 244b, the third channel pattern 244c, and the fourth channel pattern 244d may be electrically connected to different bit lines BL, respectively, and may operate independently.

Even in each of the embodiments illustrated in FIGS. 9A, 9B, 10A, and 10B, a combination of the blocking dielectric layer 242_2′, the charge storage layer 242_4′, and the tunneling dielectric layer 242_6′ described above with reference to FIGS. 8A to 8C may also be included.

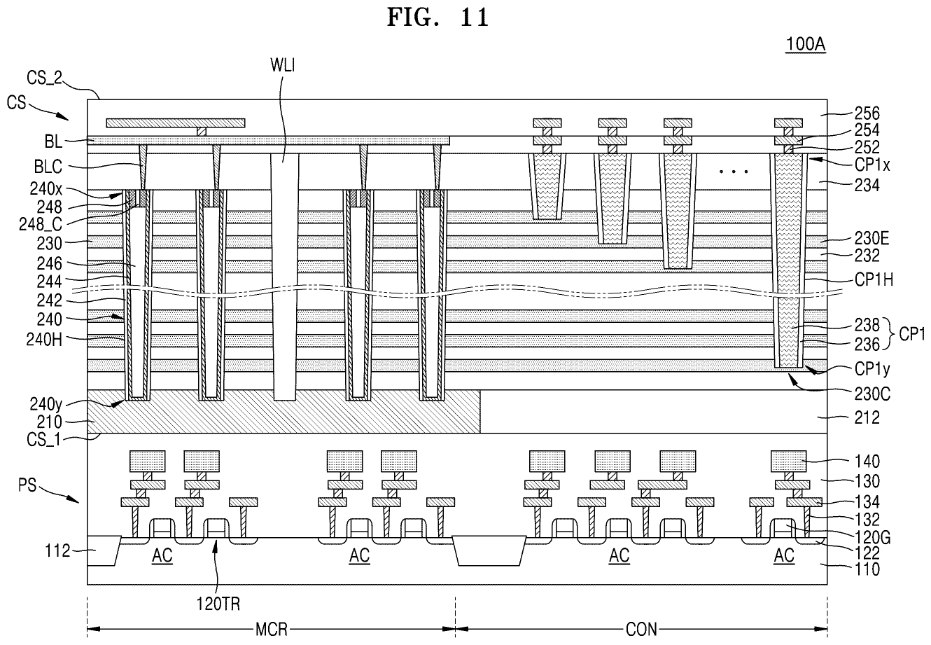

FIG. 11 is a cross-sectional view illustrating a semiconductor device 100A according to other embodiments.

Referring to FIG. 11, a common source layer 210 may be arranged on a peripheral circuit structure PS in a cell region MCR, and a buried insulating layer 212 may be arranged on the peripheral circuit structure PS in a connection region CON. A plurality of gate electrodes 230 and a plurality of mold insulating layers 232 may be arranged on the common source layer 210 and the buried insulating layer 212.

A channel structure 240 may have an inclined sidewall such that a width of a first end 240x is greater than a width of a second end 240y. The second end 240y of the channel structure 240 may be arranged close to the peripheral circuit structure PS, and the first end 240x of the channel structure 240 may be arranged far from the peripheral circuit structure PS.

In embodiments, each of a plurality of cell plugs CP1 has a first end CP1x and a second end CP1y, and the first ends CP1x of the plurality of cell plugs CP1 may all be arranged at the same vertical level, and may also be arranged at the same vertical level as the top surface of a stack cover insulating layer 234. The second end portions CP1y of the plurality of cell plugs CP1 may be arranged at different vertical levels. The second end portions CP1y of the plurality of cell plugs CP1 may be arranged close to the peripheral circuit structure PS, and the first end portions CP1x of the plurality of cell plugs CP1 may be arranged far from the peripheral circuit structure PS.

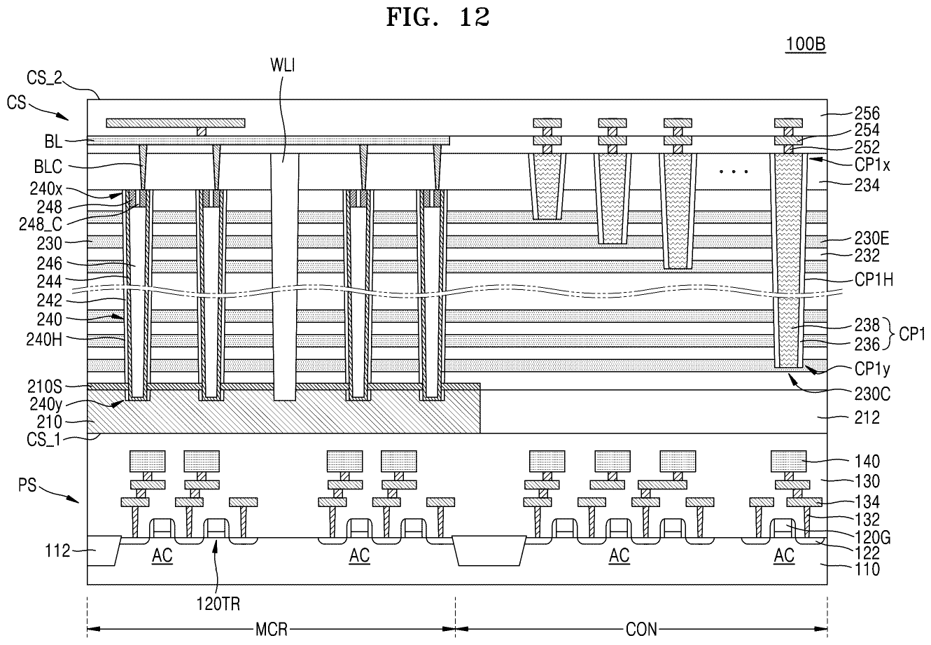

FIG. 12 is a cross-sectional view illustrating a semiconductor device 100B according to other embodiments.

Referring to FIG. 12, a horizontal semiconductor layer 210S may be arranged on a common source layer 210. In embodiments, the horizontal semiconductor layer 210S may include polysilicon doped with impurities or polysilicon undoped. The horizontal semiconductor layer 210S may function as a part of a common source region connecting the common source layer 210 and the channel layer 244 to each other.

The bottom surface of the channel layer 244 is arranged on the gate insulating layer 242 and is not in direct contact with the common source layer 210, and a sidewall of the bottom portion of the channel layer 244 may be surrounded by the horizontal semiconductor layer 210S.

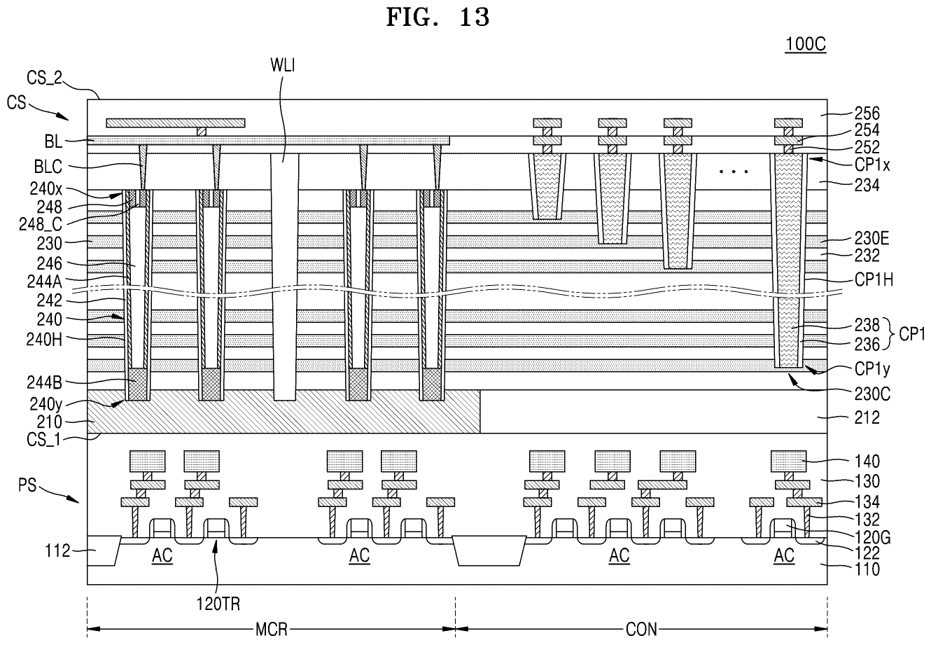

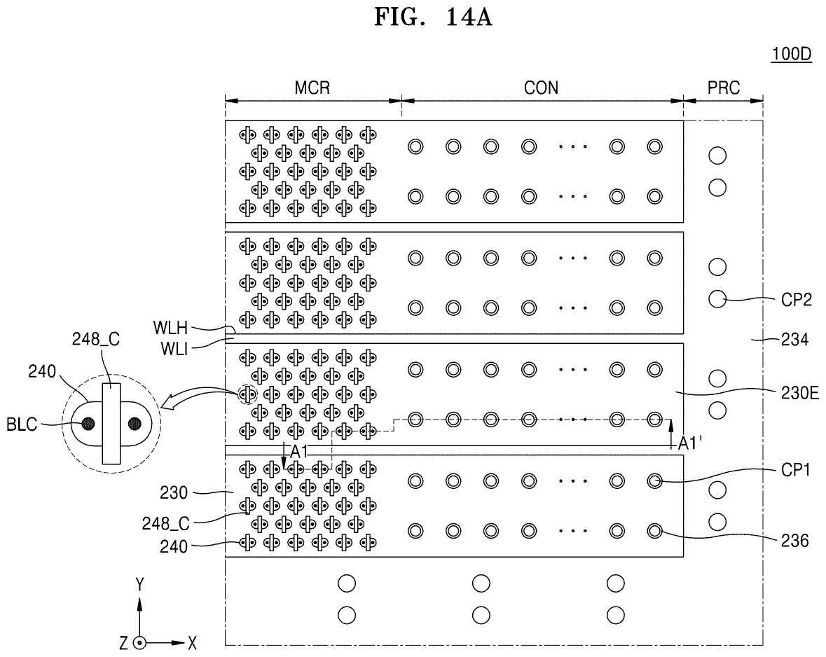

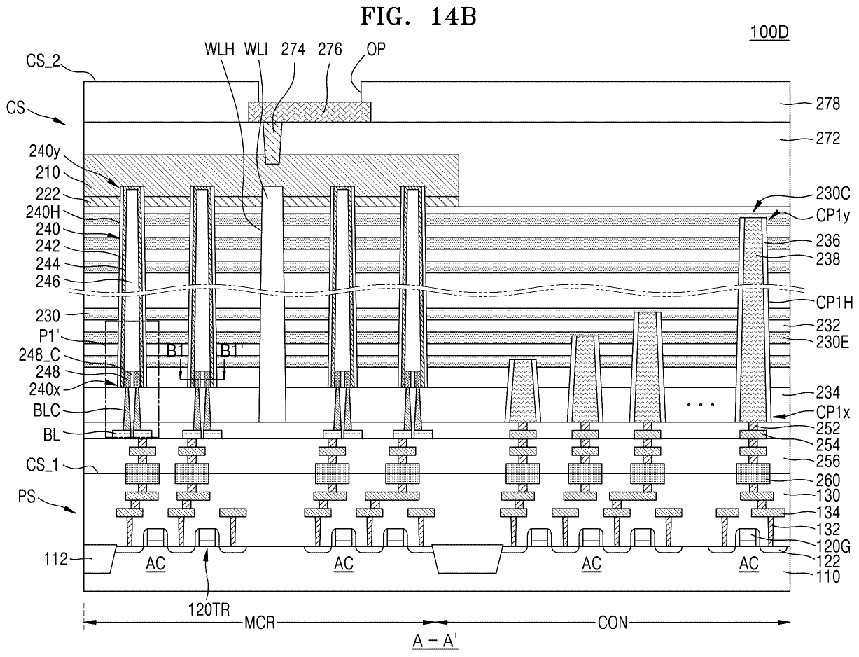

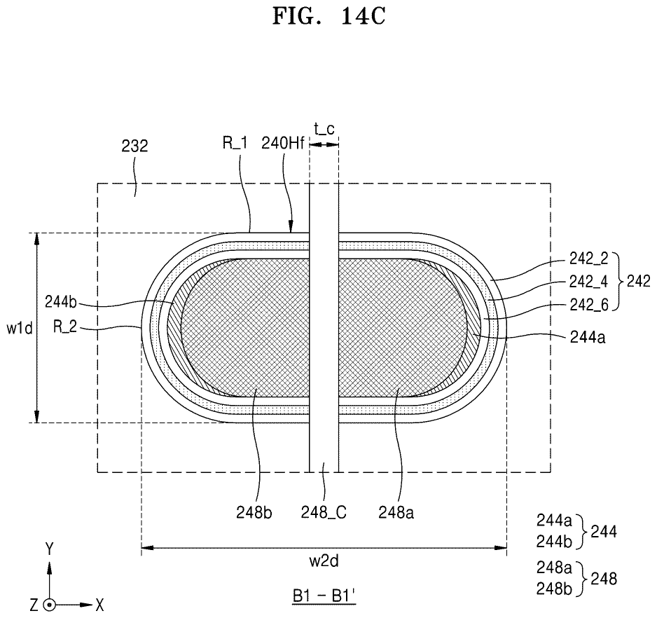

FIG. 13 is a cross-sectional view illustrating a semiconductor device 100C according to other embodiments.

Referring to FIG. 13, a channel structure 240 includes a gate insulating layer 242, a channel layer 244A, a buried insulating layer 246, and a drain region 248, and may further include a contact semiconductor layer 244B arranged on a bottom portion of the channel hole 240H. The channel layer 244A is not in direct contact with the common source layer 210, and the channel layer 244A may be electrically connected to the common source layer 210 through the contact semiconductor layer 244B. In embodiments, the contact semiconductor layer 244B may include a silicon layer formed by a selective epitaxial growth (SEG) process using, as a seed layer, the common source layer 210 arranged at the bottom of the channel hole 240H.

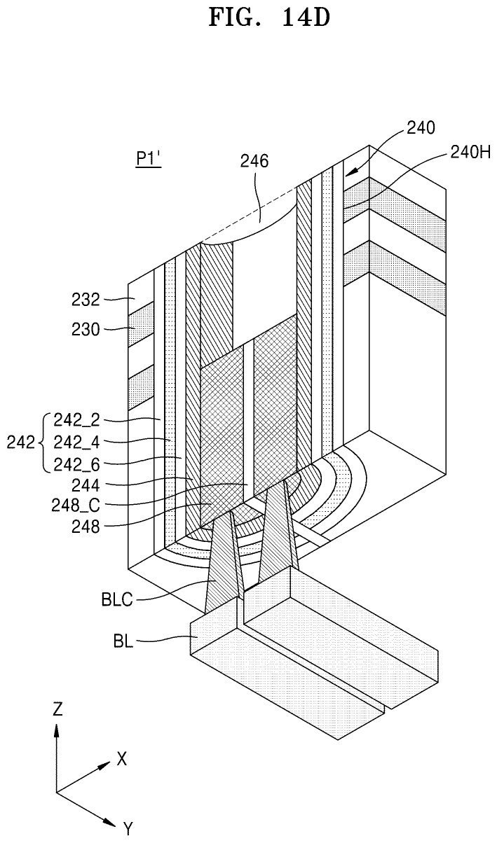

FIGS. 14A to 14D are diagrams for describing a semiconductor device 100D according to other embodiments.

In detail, FIG. 14A is a plan view illustrating a semiconductor device 100D according to other embodiments, FIG. 14B is a cross-sectional view taken along line A1-A1′ of FIG. 14A, FIG. 14C is a schematic plan view at a vertical level taken along line B1-B1′ of FIG. 14B, and FIG. 14D is a diagram a region represented by P1′ of FIG. 14B, and since the semiconductor device 100D is configured to be substantially similar to the semiconductor device 100 described with reference to FIGS. 3 to 7B, the difference will be mainly described below.

Referring to FIGS. 14A to 14D, a semiconductor device 100D includes a cell structure CS and a peripheral circuit structure PS, which overlap each other in a vertical direction (Z direction).

In embodiments, as illustrated in FIG. 14C, a channel hole 240Hf may include a pair of first regions R_1 facing each other in the second horizontal direction (Y direction) and a pair of second regions R_2 facing each other in the first horizontal direction (X direction). The channel hole 240Hf may have a first width w1d in the second horizontal direction (Y direction), and a second width w2d in the first horizontal direction (X direction), and the second width w2d may be greater than the first width w1d.

In some embodiments, the pair of first regions R_1 of the channel hole 240Hf may have a first curvature, the pair of second regions R_2 may have a second curvature, and the second curvature may be greater than the first curvature. In some embodiments, the first curvature may be zero. In other words, the pair of first regions R_1 of the channel hole 240Hf each may have a flat inner wall, and the pair of second regions R_2 of the channel hole 240Hf each may have a curved surface. In some other embodiments, the second curvature may be less than the first curvature. In some other embodiments, the second curvature may be zero. In other words, the pair of first regions R_1 of the channel hole 240Hf each may have a curved inner wall, and the pair of second regions R_2 of the channel hole 240Hf each may have a flat inner wall. The shape of the channel hole 240Hf is not limited as illustrated, and the shapes of the various channel holes described above with reference to FIGS. 9A to 10B may be employed.

In embodiments, the channel layer 244 may be arranged on the inner wall of the gate insulating layer 242 to cover a portion of the inner wall of the gate insulating layer 242, and may not cover a portion of the other remaining portions of the inner wall of the gate insulating layer 242. In some embodiments, the gate insulating layer 242 may include a combination of the blocking dielectric layer 242_2′, the charge storage layer 242_4′, and the tunneling dielectric layer 242_6′, which have been described above with reference to FIGS. 8A to 8C.

The channel layer 244 may include a plurality of channel patterns. For example, the channel layer 244 may include a first channel pattern 244a and a second channel pattern 244b. The first channel pattern 244a and the second channel pattern 244b may be arranged on the pair of second regions R_2 of the channel hole 240Hf, respectively. The first channel pattern 244a and the second channel pattern 244b may be arranged to be spaced apart from each other in the first horizontal direction (X direction), and may be electrically separated from each other. The first channel pattern 244a and the second channel pattern 244b may be electrically connected to different bit lines BL, respectively, and may operate independently.

In embodiments, a drain region 248 may include a plurality of drain patterns. For example, the drain region 248 may include a first drain pattern 248a and a second drain pattern 248b.

A drain region cut 248_C may be arranged between the first drain pattern 248a and the second drain pattern 248b. The first drain pattern 248a and the second drain pattern 248b may be spaced apart from each other in the first horizontal direction (X direction) with the drain region cut 248_C therebetween.

In some embodiments, as illustrated in FIG. 14A, the drain region cut 248_C may extend short in the second horizontal direction (Y direction) through the gate insulating layer 242. The drain region cut 248_C may penetrate one, two, or three channel structures 240 in the second horizontal direction (Y direction). The number of channel structures 240 through which the drain region cut 248_C passes is not limited as illustrated. Alternatively, the drain region cut 248_C may extend shorter in the second horizontal direction (Y direction) to penetrate only the drain region 248 without penetrating the gate insulating layer 242. The thickness t_c of the drain region cut 248_C in the first horizontal direction (X direction) is not limited, but may be formed to be less than or equal to the minimum separation distance between the first channel pattern 244a and the second channel pattern 244b (e.g., a separation distance on the tunneling dielectric layer 242_6 between the first channel pattern 244a and the second channel pattern 244b). In some embodiments, the thickness t_c of the drain region cut 248_C in the first horizontal direction (X direction) on the layout may be within about 20 nanometers to about 80 nanometers.

Since the drain region cut 248_C in embodiments of the inventive concept is formed to penetrate the drain region 248 of the channel structure 240 and thus has a relatively short vertical length, the thickness of the drain region cut 248_C in the horizontal direction on the layout may be relatively thin, and the size of the channel structure 240 on the layout may be formed relatively small, thereby providing a semiconductor device with improved integration.

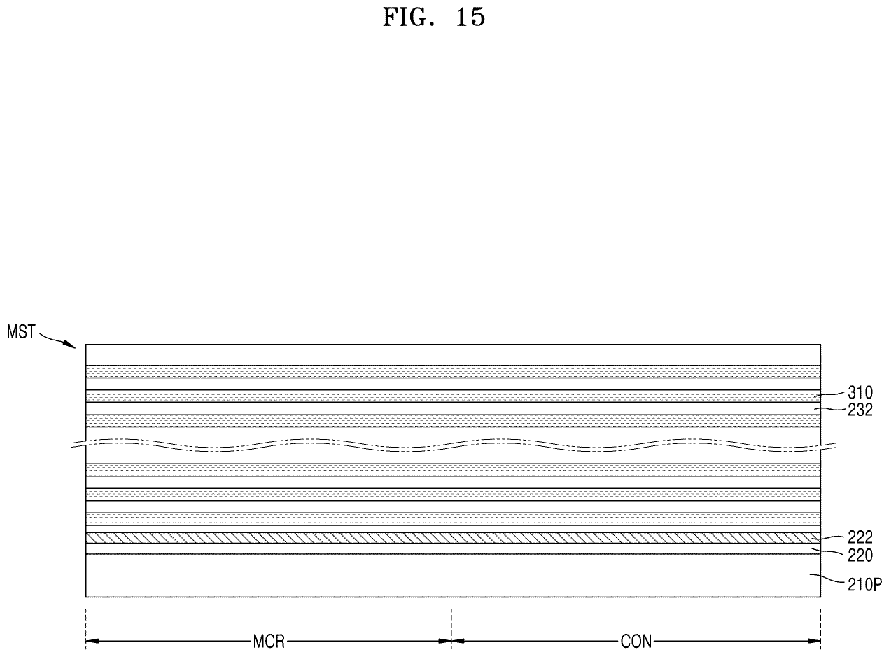

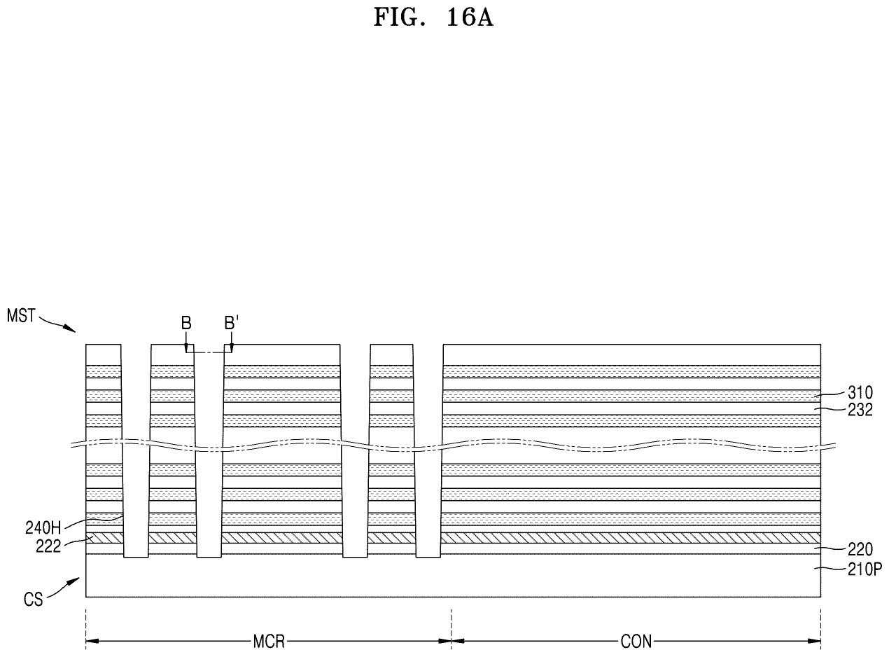

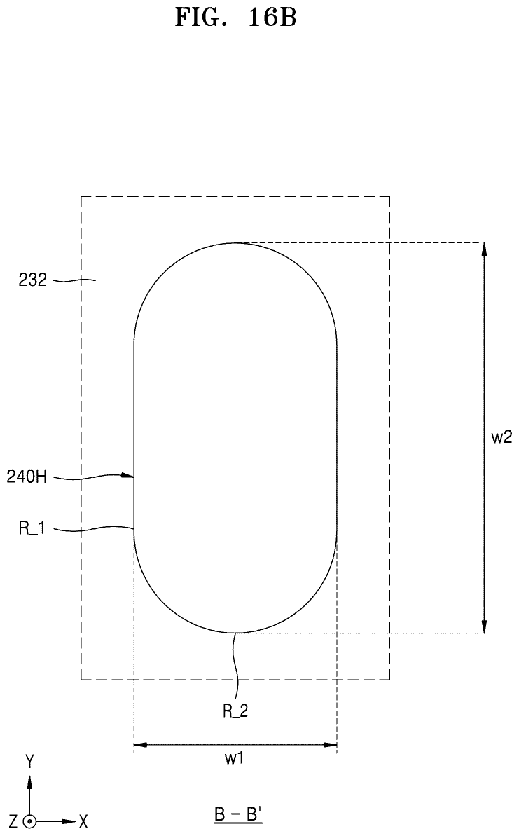

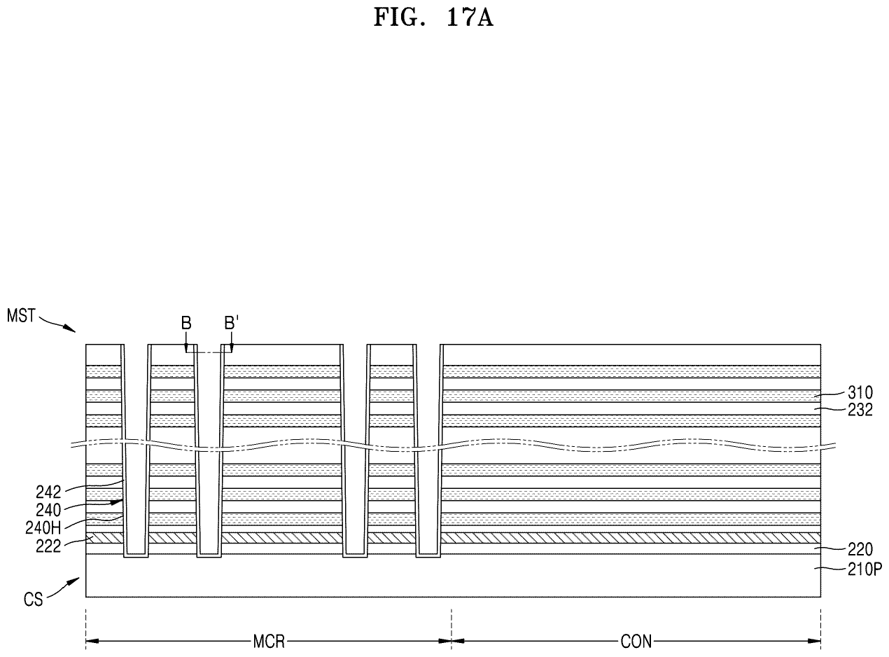

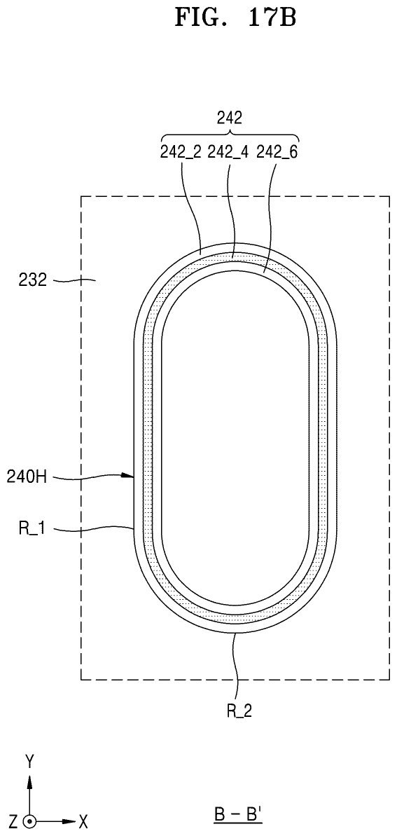

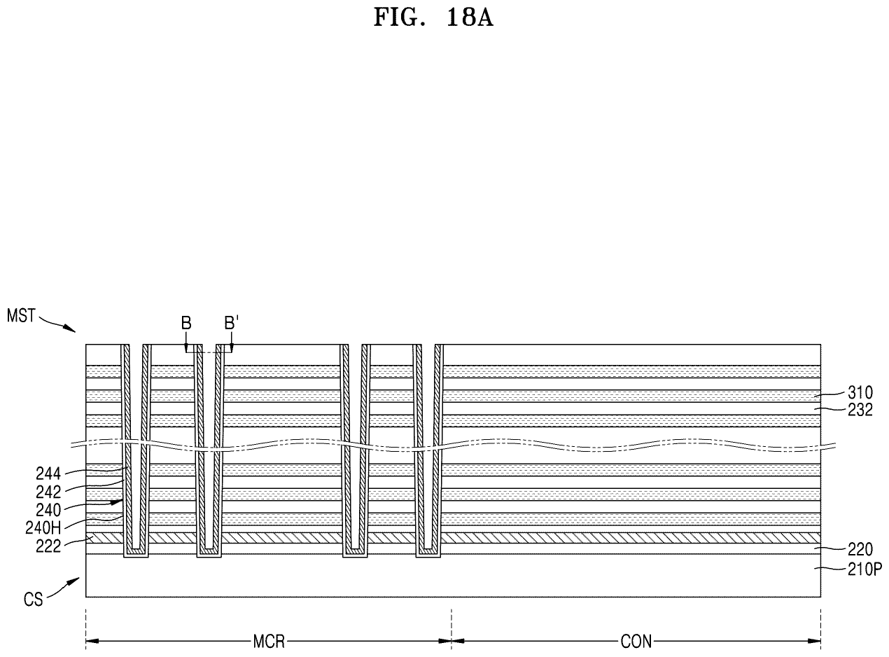

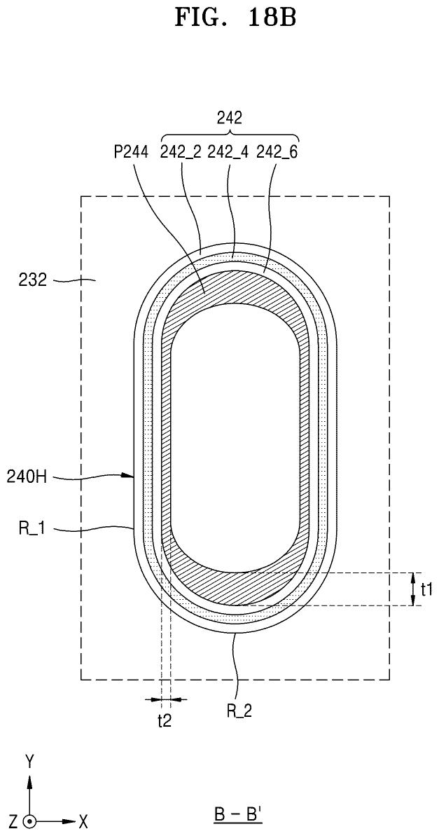

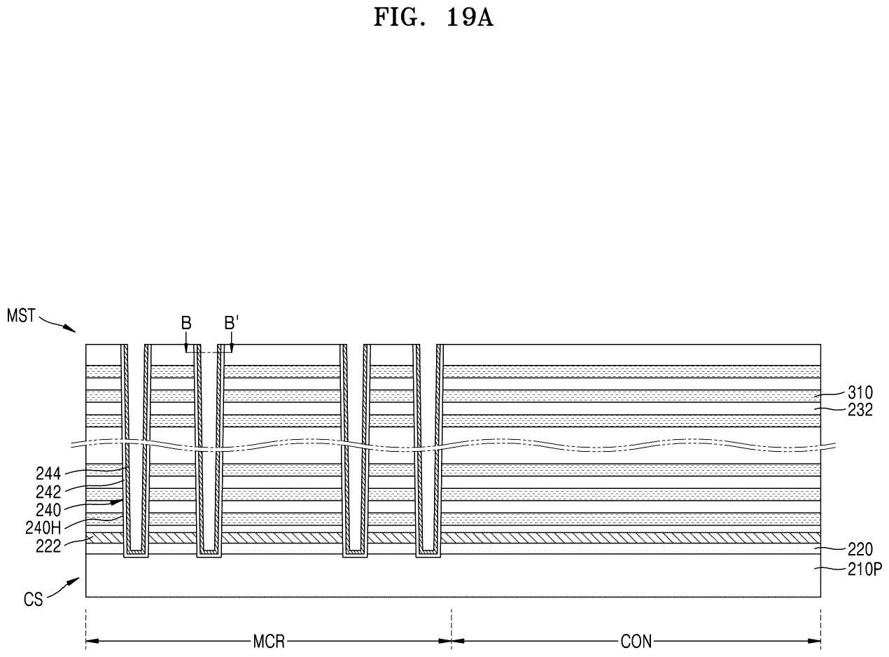

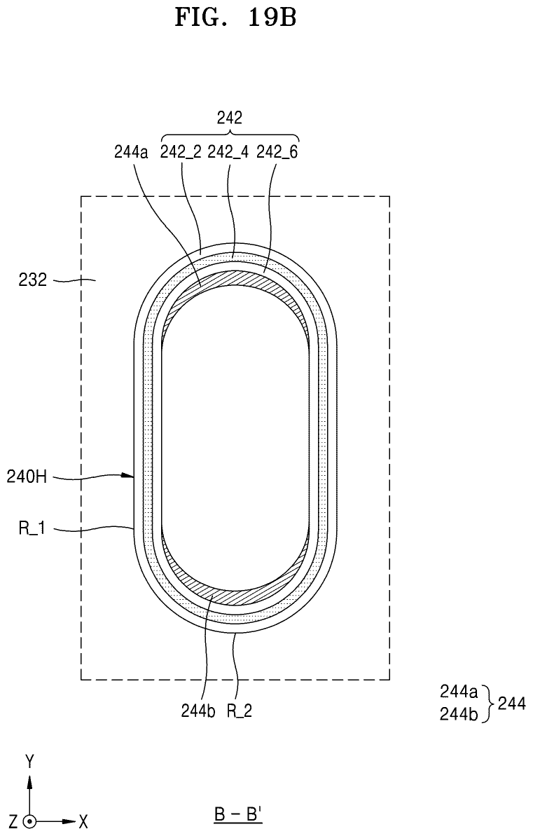

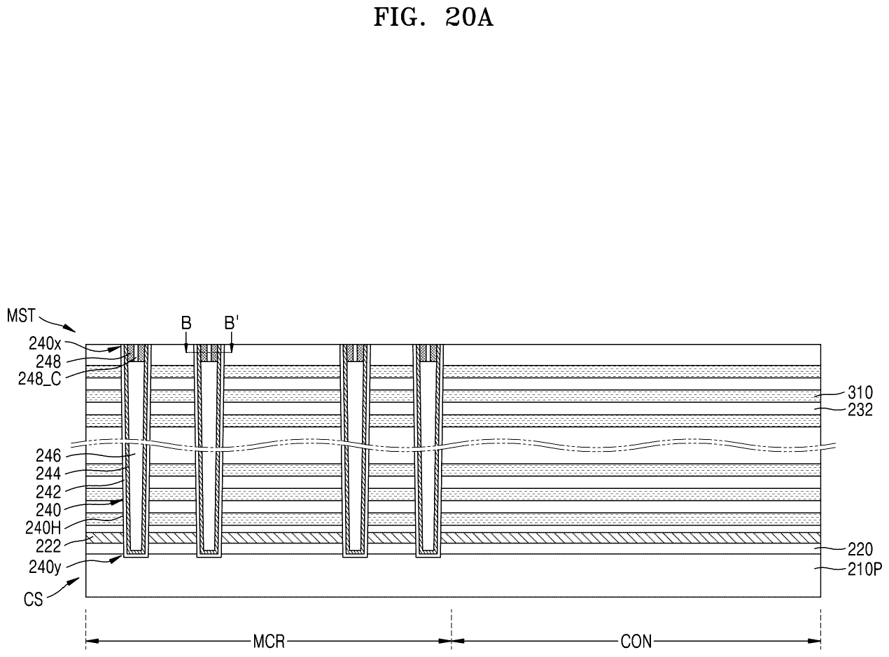

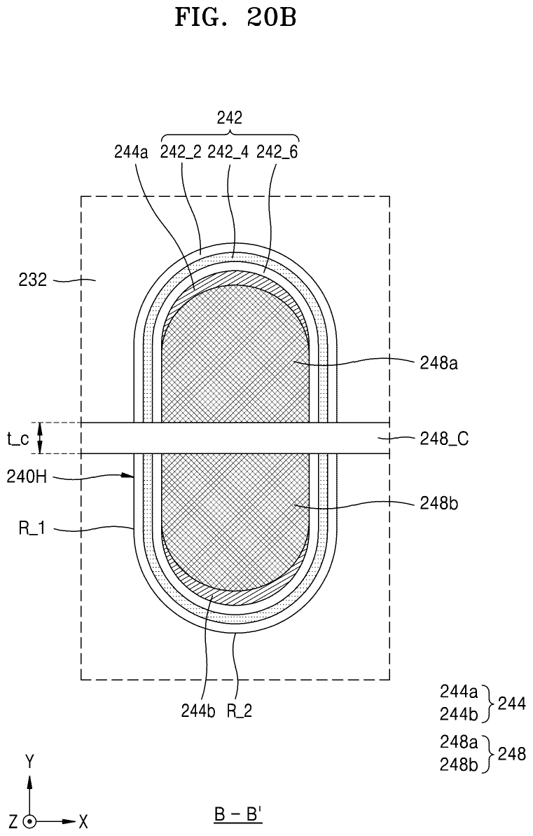

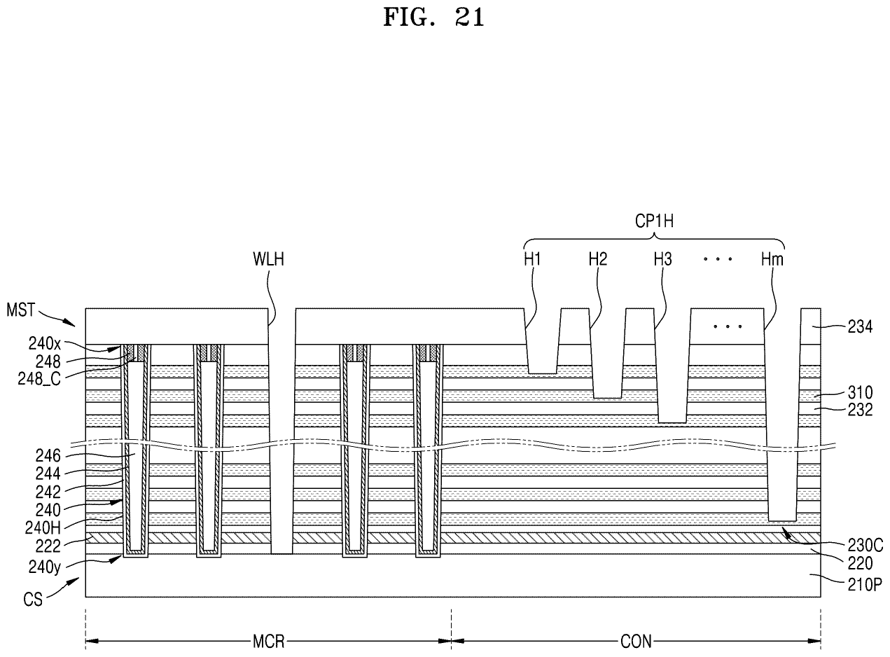

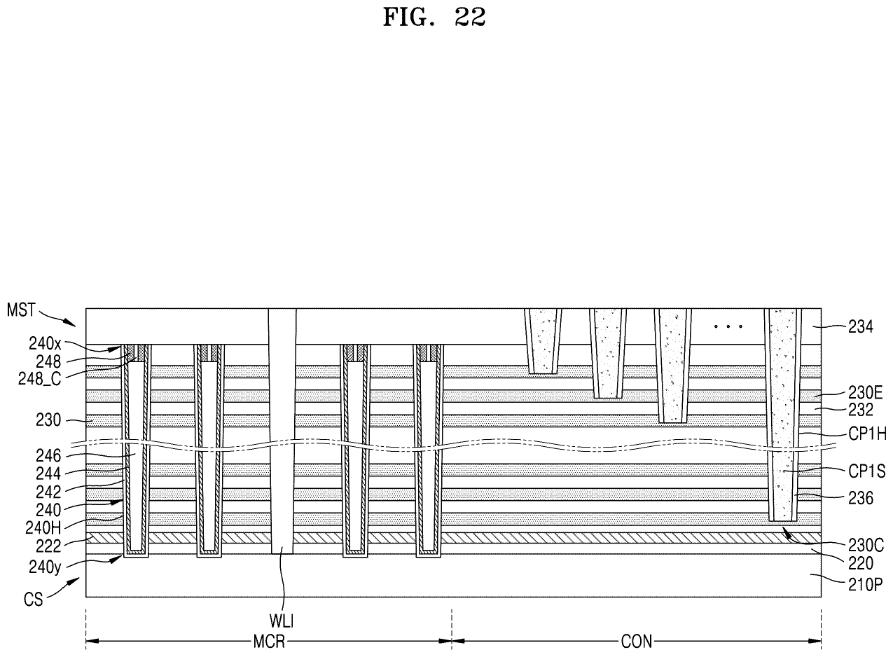

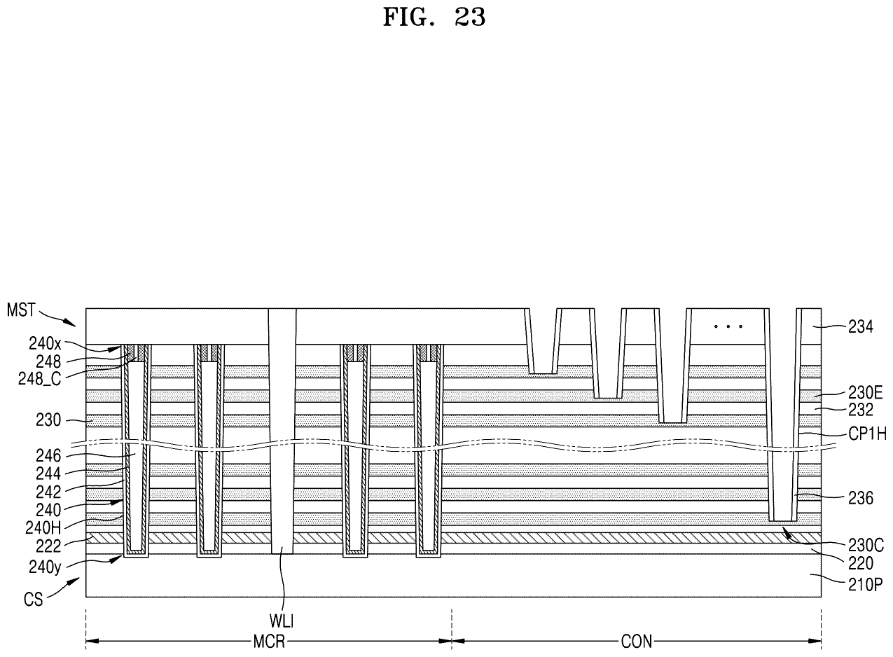

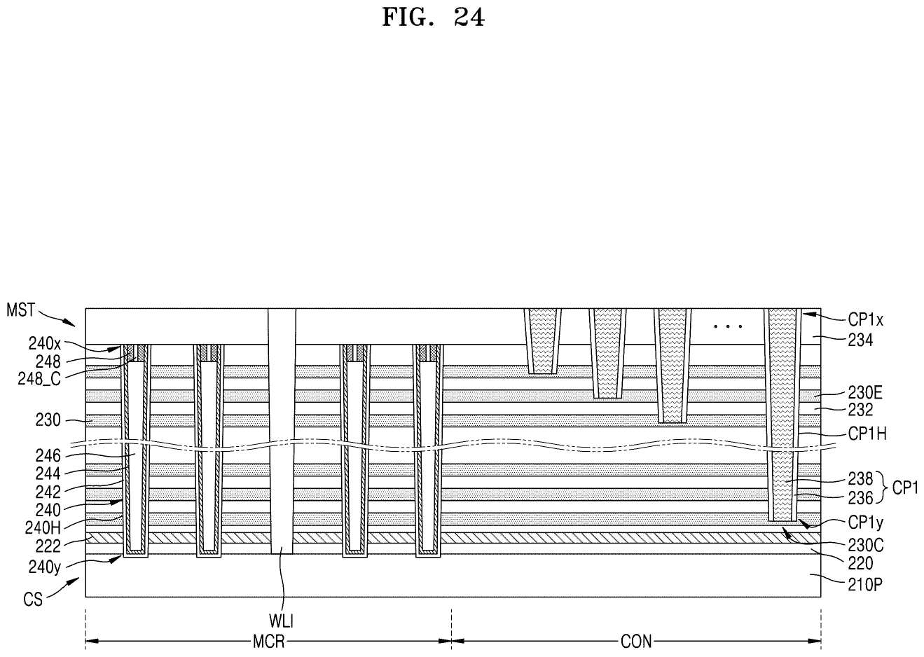

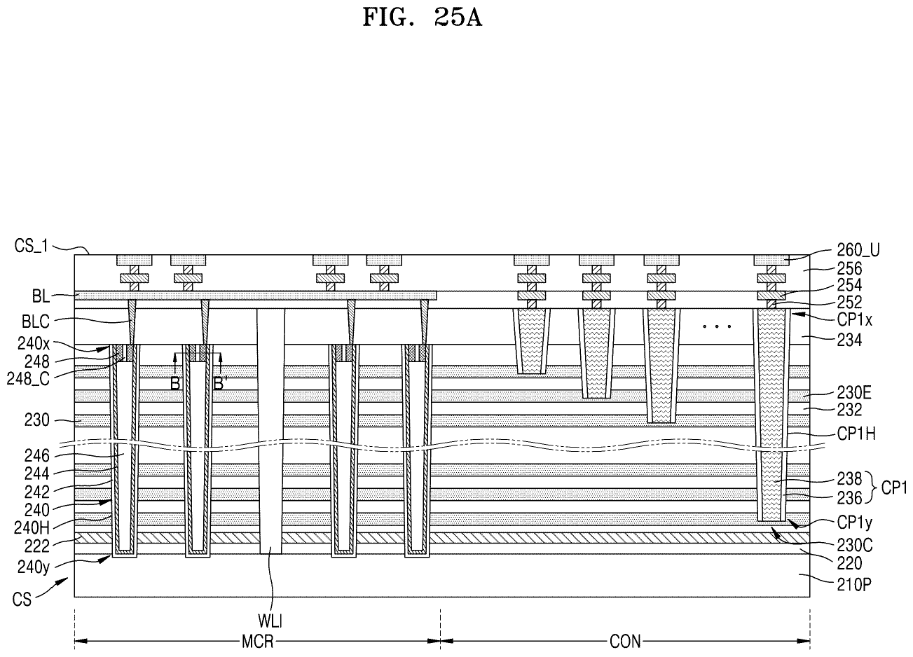

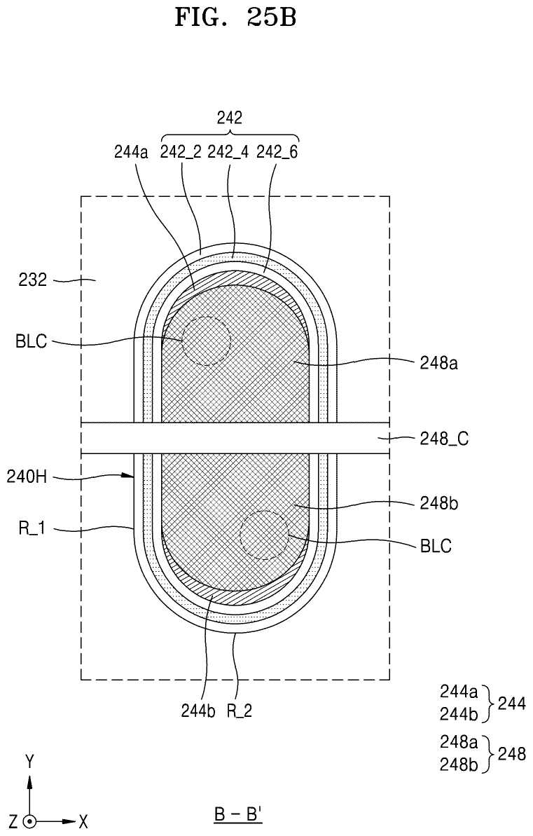

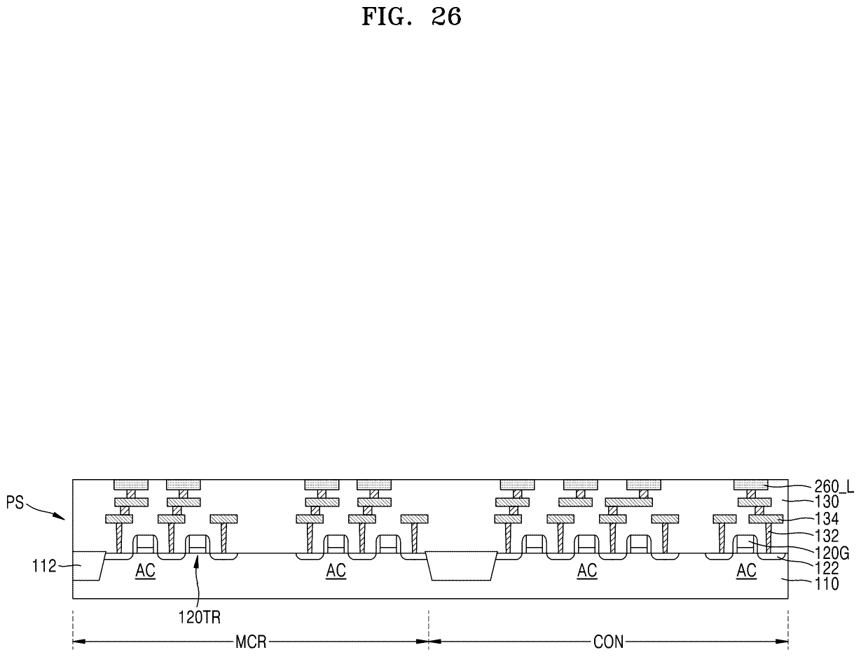

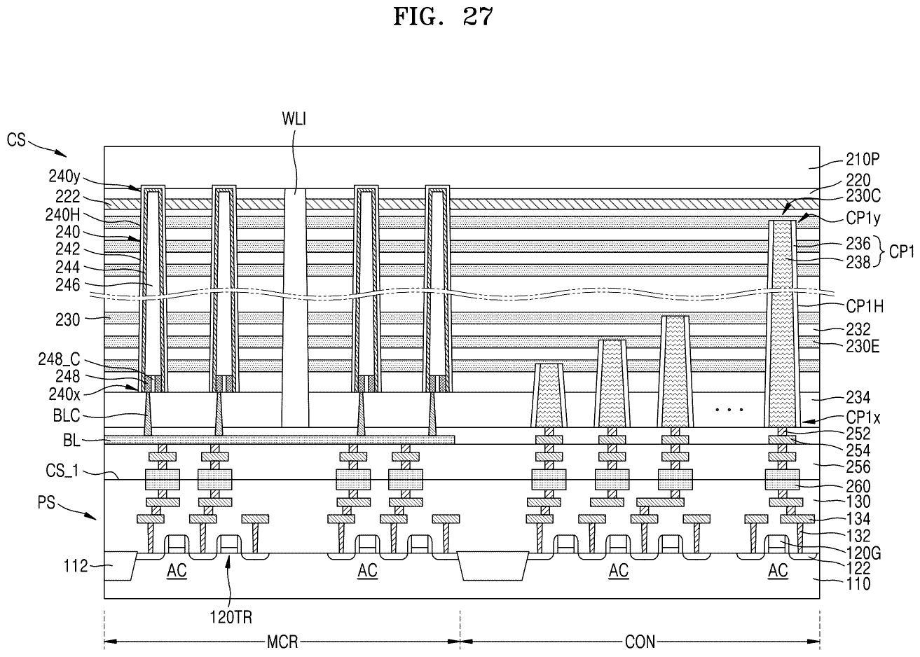

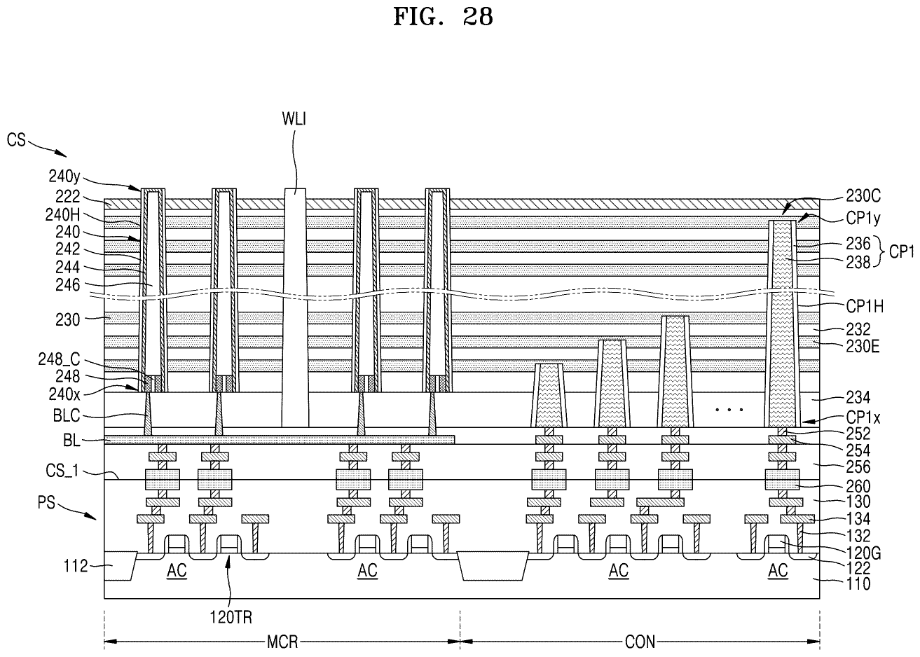

FIGS. 15 to 30 are cross-sectional views illustrating a method of manufacturing a semiconductor device according to embodiments, in which, in detail, FIGS. 15, 16A, 17A, 18A, 19A, 20A, and 21 to 30 are cross-sectional views respectively corresponding to a cross-section taken along line A-A′ of FIG. 4, and FIGS. 16B, 17B, 18B, 19B, 20B, and 25B are schematic plan views respectively corresponding to a plane at a vertical level taken along line B-B′ of FIGS. 16A, 17A, 18A, 19A, 20A, and 25A.

Referring to FIG. 15, a buffer insulating layer 220 may be formed on a cell substrate 210P, and an etching stop layer 222 may be formed on the buffer insulating layer 220.

In embodiments, the cell substrate 210P may include at least one of silicon (Si), germanium (Ge), silicon germanium (SiGe), gallium arsenide (GaAs), indium gallium arsenide (InGaAs), aluminum gallium arsenide (AlGaAs), or a mixture thereof. The buffer insulating layer 220 may be formed using silicon oxide. In embodiments, an etching stop layer 222 may be formed using polysilicon.

Thereafter, a mold stack MST may be formed by alternately forming sacrificial layers 310 and a plurality of mold insulating layers 232 on the etching stop layer 222 in a cell region MCR and a connection region CON. In some embodiments, the sacrificial layers 310 and the plurality of mold insulating layers 232 may be formed using materials having etch selectivity with respect to each other. For example, the sacrificial layers 310 may include silicon nitride, and the plurality of mold insulating layers 232 may include silicon oxide.

Referring to FIGS. 16A and 16B, a channel hole 240H extending in a vertical direction (Z direction) through the mold stack MST may be formed in the cell region MCR. In embodiments, the channel hole 240H may extend in the vertical direction Z through the mold stack MST, the etching stop layer 222, and the buffer insulating layer 220, and a top surface of the cell substrate 210P may be exposed at the bottom of the channel hole 240H.

The channel hole 240H may include a pair of first regions R_1 facing each other in the first horizontal direction (X direction) and a pair of second regions R_2 facing each other in the second horizontal direction (Y direction). The channel hole 240H may have a first width w1 in the first horizontal direction (X direction), and a second width w2 in the second horizontal direction (Y direction), and the second width w2 may be greater than the first width w1. However, the shape of the channel hole 240H is not limited to the illustration, and the channel holes 240Hb, 240Hc, 240Hd, 240He, and 240Hf of various shapes described above may be employed.

Referring to FIGS. 17A and 17B, a gate insulating layer 242 may be formed on an inner wall of the channel hole 240H. In order to form the gate insulating layer 242, a blocking dielectric layer 242_2, a charge storage layer 242_4, and a tunneling dielectric layer 242_6 may be sequentially formed on the inner wall of the channel hole 240H.

In some embodiments, to form a first blocking dielectric pattern 242_2a and a second blocking dielectric pattern 242_2b, such as the blocking dielectric layer 242_2′ of FIG. 8A, a preliminary blocking dielectric layer may be formed to have a greater thickness on the second region R_2 than a thickness on the first region R_1. Thereafter, by isotropically etching the preliminary blocking dielectric layer in the channel hole 240H, a portion of the preliminary blocking dielectric layer having a relatively thin thickness on the first region R_1 may be removed to expose a portion of the inner wall of the channel hole 240H, and the first blocking dielectric pattern 242_2a and the second blocking dielectric pattern 242_2b spaced apart from each other may be formed.

In some embodiments, to form a first charge storage pattern 242_4a and a second charge storage pattern 242_4b, such as the charge storage layer 242_4′ of FIG. 8B, a preliminary charge storage layer may be formed to have a thickness greater on the second region R_2 than a thickness on the first region R_1. Thereafter, by isotropically etching the preliminary charge storage layer in the channel hole 240H, a portion of the preliminary charge storage layer having a relatively thin thickness on the first region R_1 may be removed to expose a portion of the inner wall of the blocking dielectric layer 242_2, and the first charge storage pattern 242_4a and the second charge storage pattern 242_4b spaced apart from each other may be formed.

In some embodiments, to form a first tunneling dielectric pattern 242_6a and a second tunneling dielectric pattern 242_6b, as in the tunneling dielectric layer 242_6′ of FIG. 8C, a preliminary tunneling dielectric layer may be formed to have a greater thickness on the second region R_2 than a thickness on the first region R_1. Thereafter, by isotropically etching the preliminary tunneling dielectric layer in the channel hole 240H, a portion of the preliminary tunneling dielectric layer having a relatively thin thickness on the first region R_1 may be removed to expose a portion of the inner wall of the charge storage layer 242_4, and a first tunneling dielectric pattern 242_6a and a second tunneling dielectric pattern 242_6b spaced apart from each other may be formed.

In the process of forming the preliminary blocking dielectric layer, the preliminary charge storage layer, or the preliminary tunneling dielectric layer, the process conditions may be adjusted so that the deposition amount per hour on the first region R_1 and the deposition amount per hour on the second region R_2 are different from each other to have a relatively thin thickness on the first region R_1 and a relatively thick thickness on the second region R_2. Since the first width w1 of the channel hole 240H in the first horizontal direction (X direction) is longer than the second width w2 in the second horizontal direction (Y direction), the deposition area on the first region R_1 is wider than the deposition area on the second region R_2, the deposition amount per hour on the second region R_2 may be greater than the deposition amount per hour on the first region R_1, and the process conditions may be adjusted to maximize the difference in the deposition amounts per hour. For example, process conditions may be adjusted by adjusting the process temperature to a relatively low temperature, reducing the number of vacuum exhaust or purge gas injection processes, or supplying or not supplying relatively little inhibitor gas.

Referring to FIGS. 18A and 18B, a preliminary channel layer P244 may be formed on an inner wall of the gate insulating layer 242 in the channel hole 240H. The process conditions may be adjusted such that the preliminary channel layer P244 has a first thickness t1 in the first region R_1 and a second thickness t2 in the second region R_2 that is greater than the first thickness t1, and such that the deposition amount per hour in the second region R_2 is greater than the deposition amount per hour in the first region R_1. The process conditions may be adjusted in a manner similar to the process conditions in the process of depositing the gate insulating layer 242 described with reference to FIGS. 17A and 17B.

Referring to FIGS. 19A and 19B, from a result of FIGS. 18A and 18B, the preliminary channel layer P244 is isotropically etched in the channel hole 240H to remove a portion of the preliminary channel layer P244 having a relatively thin thickness on the first region R_1 so that a portion of the inner wall of the gate insulating layer 242 (e.g., a portion of the tunneling dielectric layer 242_6) may be exposed, and a first channel pattern 244a and a second channel pattern 244b spaced apart from each other may be formed. Since the first width w1 of the channel hole 240H in the first horizontal direction (X direction) is longer than the second width w2 in the second horizontal direction (Y direction), the deposition area on the first region R_1 is wider than the deposition area on the second region R_2, the deposition amount per hour on the second region R_2 may be greater than the deposition amount per hour on the first region R_1, and the first channel pattern 244a and the second channel pattern 244b may be formed on the pair of second regions R_2.

Referring to FIGS. 20A and 20B, a buried insulating layer 246 may be formed on an inner wall of the channel layer 244 in a channel hole 240H, and a drain region 248 may be formed on an upper portion of the buried insulating layer 246. Thereafter, a drain region cut 248_C penetrating the drain region 248 in the vertical direction (Z direction) may be formed. The drain region cut 248_C may be formed by etching a portion of the drain region 248 so that a portion of the top surface of the buried insulating layer 246 may be exposed, and then filling an insulating material in the region from which the portion of the drain region 248 has been removed. The bottom surface of the drain region cut 248_C may be in contact with the top surface of the buried insulating layer 246.

A first drain pattern 248a and a second drain pattern 248b electrically separated from each other may be formed by the drain region cut 248_C.

In some embodiments, as illustrated in FIG. 4, the drain region cut 248_C may extend long in the first horizontal direction (X direction) through the gate insulating layer 242. However, in some other embodiments, although not illustrated, the drain region cut 248_C may extend short in the first horizontal direction (X direction) to penetrate one, two, or three channel structures 240. The number of channel structures 240 through which the drain region cut 248_C passes is not limited as illustrated. Alternatively, the drain region cut 248_C may extend shorter in the first horizontal direction (X direction) to penetrate only the drain region 248 without penetrating the gate insulating layer 242. Although a thickness t_c of the drain region cut 248_C is not limited, it may be advantageous to form the thickness t_c to be less than or equal to the minimum separation distance between the first channel pattern 244a and the second channel pattern 244b (e.g., the separation distance on the tunneling dielectric layer 242_6 between the first channel pattern 244a and the second channel pattern 244b) to improve the degree of integration of the semiconductor device.

Referring to FIG. 21, a stack cover insulating layer 234 may be formed on the top surface of the mold stack MST. The stack cover insulating layer 234 may cover the entire top surface of the mold stack MST in the cell region MCR and the connection region CON. The stack cover insulating layer 234 has flat top surface and bottom surface levels over the entire cell region MCR and the entire connection region CON, and may have a constant thickness over the entire cell region MCR and the entire connection region CON.

Thereafter, a stack isolation opening WLH extending in the vertical direction Z through the mold stack MST and the stack cover insulating layer 234 may be formed in the cell region MCR and the connection region CON. The stack isolation opening WLH may extend in the first horizontal direction (X direction) (see FIG. 4) in the cell region MCR and the connection region CON.

In some embodiments, a dummy channel hole extending in the vertical direction (Z direction) through the mold stack MST may be formed in the connection region CON. In some embodiments, the process for forming the dummy channel hole may be simultaneously performed in the etching process for forming the stack isolation opening WLH. In other embodiments, the process for forming the dummy channel hole may be performed simultaneously in the etching process for forming the channel structure 240.

A plurality of cell plug holes CP1H) extending in the vertical direction (Z direction) may be formed by removing portions of the stack cover insulating layer 234 and the mold stack MST in the connection region CON. The plurality of cell plug holes CP1H may have heights varying in the vertical direction (Z direction). The plurality of cell plug holes CP1H may have different heights to expose a top surface of a corresponding sacrificial layer 310 among the plurality of sacrificial layers 310.

For example, the cell plug holes CP1H may include a first hole H1 exposing the top surface of the uppermost sacrificial layer 310, a second hole H2 exposing the top surface of the sacrificial layer 310 directly below the uppermost sacrificial layer 310 (e.g., a second hole H2 exposing the top surface of the second uppermost sacrificial layer 310), a third hole H3 exposing the top surface of the third sacrificial layer 310 from the top surface of the mold stack MST, and an m-th hole Hm exposing the top surface of the m-th sacrificial layer 310 from the top surface of the mold stack MST.

Referring to FIG. 22, an insulating liner 236 and a sacrificial pillar CP1S may be sequentially formed in the cell plug holes CP1H (referring to FIG. 21). The insulating liner 236 may include oxide or silicon oxide. The sacrificial pillar CP1S may include a conductive material such as tungsten, a silicon layer, a polycrystalline silicon layer, or a carbonized layer, but is not limited thereto.

Thereafter, the sacrificial layers 310 exposed to the inner wall of the stack isolation opening WLH may be removed. Thereafter, the gate electrode 230 may be formed using a metal material in the space from which the sacrificial layers 310 have been removed. Thereafter, a stack isolation insulating layer WLI may be formed in the stack isolation opening WLH.

As the plurality of sacrificial layers 310 are replaced with the plurality of gate electrodes 230, the plurality of gate electrodes 230 may extend in the horizontal direction on the cell region MCR and the connection region CON. The plurality of gate electrodes 230 arranged on the connection region CON are referred to as gate extension portions 230E. A plurality of gate extension portions 230E may overlap each other in a vertical direction (Z direction) on the connection region CON. For example, the plurality of gate extension portions 230E arranged at different vertical levels on the connection region CON may have the same width in the horizontal direction.

Referring to FIG. 23, the sacrificial pillars CP1S arranged in the cell plug holes CP1H may be removed, and an etch-back process may be performed on the bottom portions of the plurality of cell plug holes CP1H to expose the top surfaces of the gate extension portions 230E by removing some of the bottom portions of the plurality of cell plug holes CP1H among the insulating liners 236. For example, a portion of the insulating liner 236 covering the top surfaces of the gate extension portions 230E may be removed by the etch-back process, and the top surfaces of the gate extension portions 230E may be exposed. The top surfaces of the exposed gate extension portions 230E may be referred to as the gate contact surfaces 230C.

Referring to FIG. 24, a plurality of conductive plugs 238 may be formed inside a plurality of cell plug holes CP1H. Thus, the cell plug CP1 consisting of the conductive plug 238 and the insulating liner 236 may be formed. In embodiments, the cell plug CP1 has a first end CP1x and a second end CP1y, the first end CP1x of the cell plug CP1 may be arranged at the same vertical level as a top surface of the stack cover insulating layer 234, and the second end CP1y may be placed on each corresponding gate contact surface 230C.

In embodiments, a bottom surface of each of the plurality of conductive plugs 238 may be in contact with a gate contact surface 230C, and accordingly, one conductive plug 238 may be electrically connected to the corresponding gate extension portion 230E through the gate contact surface 230C. For example, the bottom surface of one conductive plug 238 may be electrically connected to the corresponding gate extension portion 230E, while the sidewall of one conductive plug 238 may not be electrically connected to the corresponding gate extension portion 230E by the insulating liner 236 arranged between the conductive plug 238 and the plurality of gate electrodes 230.

Referring to FIGS. 25A and 25B, a bit line contact BLC and a bit line BL electrically connected to a channel structure 240 may be formed. A bit line contact BLC connected to the first drain pattern 248a and a bit line contact BLC connected to the second drain pattern 248b may be formed. Each of the first channel pattern 244a and the second channel pattern 244b may be connected to the bit line BL through the first drain pattern 248a, the second drain pattern 248b, and the bit line contact BLC. The bit line contact BLC and the bit line BL to which the first drain pattern 248a and the first channel pattern 244a are electrically connected may be different from the bit line contact BLC and the bit line BL to which the second drain pattern 248b and the second channel pattern 244b are electrically connected.

Thereafter, a connection via 252, a connection wiring layer 254, and an interlayer insulating layer 256 electrically connected to the bit line BL and the cell plug CP1 may be formed. A connection pad 260 may be formed on a top surface of the interlayer insulating layer 256.

Referring to FIG. 26, a peripheral circuit structure PS may be prepared.

The peripheral circuit transistor 120TR is formed on the substrate 110 in which the active region AC is defined by the device isolation layer 112, the plurality of peripheral circuit contacts 132 and the plurality of peripheral circuit wiring layers 134 electrically connected to the plurality of peripheral circuit transistors 60TR and the substrate 110 are formed on the substrate 110, and then the interlayer insulating layer 130 covering the plurality of peripheral circuit transistors 60TR, the plurality of peripheral circuit contacts 132, and the plurality of peripheral circuit wiring layers 134 may be formed on the substrate 110. The connection pad 260_L may be formed on a top surface of the interlayer insulating layer 130.

Referring to FIG. 27, the peripheral circuit structure PS may be attached to the cell structure CS. The peripheral circuit structure PS and the cell structure CS may be attached through the connection pad 260 and the interlayer insulating layers 130 and 256 in a metal-oxide hybrid bonding method, but are not limited thereto.

Thereafter, the structure to which the peripheral circuit structure PS and the cell structure CS are attached may be reversed so that the substrate 110 faces upward.

Referring to FIG. 28, the cell substrate 210P of FIG. 27 may be removed. The cell substrate 210P may be removed by a grinding process and a subsequent etching process, and the buffer insulating layer 220 may be exposed. Thereafter, the buffer insulating layer 220 may also be removed and a top surface of the etching stop layer 222 may be exposed. As the buffer insulating layer 220 is removed, the second end 240y of the channel structure 240 may protrude toward the top surface of the etching stop layer 222.

As the cell substrate 210P and the buffer insulating layer 220 are removed, the upper side of the stack isolation insulating layer WLI may also be exposed to protrude above the etching stop layer 222.

Thereafter, the top surface of the channel layer 244 may be exposed by removing a portion of the gate insulating layer 242 exposed to the second end 240y of the channel structure 240. In some embodiments, the top surface of the gate insulating layer 242 may be arranged in the same plane as the top surface of the channel layer 244.

In other embodiments, a process of removing the gate insulating layer 242 may be performed until the top surface of the etching stop layer 222 is exposed. In some embodiments, the gate insulating layer 242 may be arranged at a level lower than the top surface of the channel layer 244 and the upper side of the gate insulating layer 242 may be removed so that the top surface and a portion of the sidewall of the channel layer 244 are exposed.

Referring to FIG. 29, a common source layer 210 may be formed in the cell region MCR, the connection region CON, and the peripheral circuit connection region PCR. The common source layer 210 may be formed using polysilicon. For example, the common source layer 210 may be formed using polysilicon doped with n-type impurities. In the cell region MCR, the common source layer 210 may be conformally formed on the exposed top surfaces of the etching stop layer 222 and the channel layer 244.

The portion of the common source layer 210 and the portion of the etching stop layer 222 arranged in the connection region CON and the peripheral circuit connection region PRC may be removed.

Referring to FIG. 30, an upper insulating layer 272 may be formed on the common source layer 210 and the uppermost mold insulating layer 232 in the cell region MCR, the connection region CON, and the peripheral circuit connection region PCR.

Thereafter, a mask pattern may be formed on the upper insulating layer 272, and a rear contact hole may be formed by removing a portion of the upper insulating layer 272 using the mask pattern as an etching mask. A common source contact 274 may be formed in the rear contact hole, and a rear wiring layer 276 electrically connected to the common source contact 274 may be formed on the upper insulating layer 272.

Thereafter, a passivation layer 278 covering the rear wiring layer 276 may be formed on the upper insulating layer 272, and an opening OP may be formed in the passivation layer 278 to expose the top surface of the rear wiring layer 276.

The semiconductor device 100 may be completely formed by performing the processes described above.

As a comparative example, in a method of manufacturing a semiconductor device that penetrates a channel structure and separates a channel layer into two channel patterns by including a hole cut formed thereon, a thickness of the hole cut in the horizontal direction is relatively thick as long as the hole cut is formed in a long vertical length to penetrate the channel structure. As a result, there is a problem in that the size of the channel structure on the layout should be relatively large.

According to the inventive concept, a preliminary channel layer P244 having a second thickness t2 in the second region R_2 greater than the first thickness t1 in the first region R_1 by making a difference in deposition amounts per hour on the first region R_1 and the second region R_2 of the channel hole 240H is formed, and is isotropically etched to form a first channel pattern 244a and a second channel pattern 244b separated from each other by removing a portion of the preliminary channel layer P244 in the first region R_1. Aa s result, according to the method of manufacturing a semiconductor device according to an embodiment of the present inventive concept, even if a hole cut is not formed, a plurality of separated channel patterns may be included.

In addition, since the drain region cut 248_C is formed to penetrate the drain region 248 of the channel structure 240 and thus has a shorter vertical length than the hole cut, the thickness of the drain region cut 248_C in the horizontal direction may be relatively thin, and the size of the channel structure 240 on the layout may be formed relatively small, thereby providing a method of manufacturing a semiconductor device with improved integration.

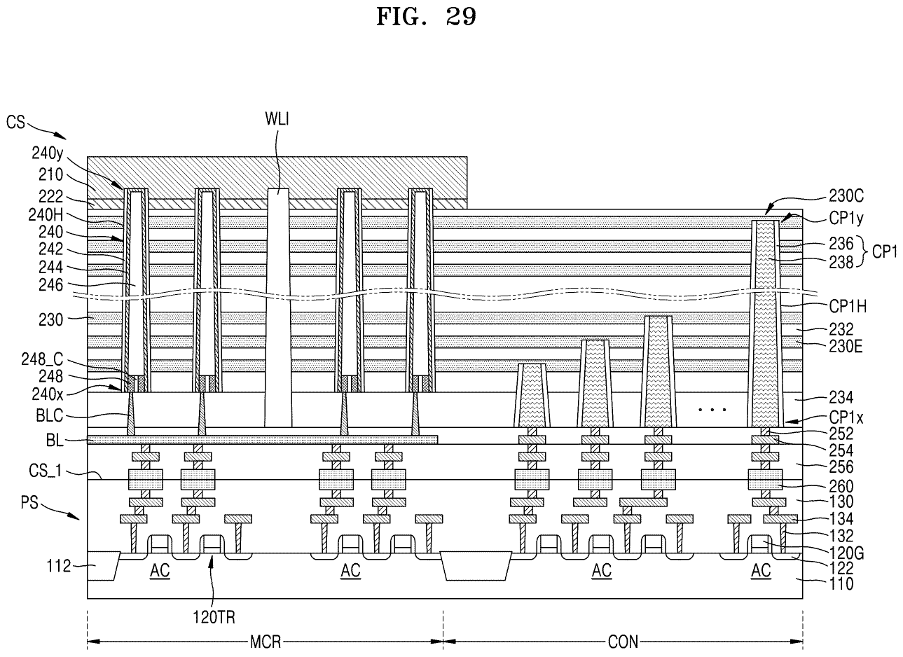

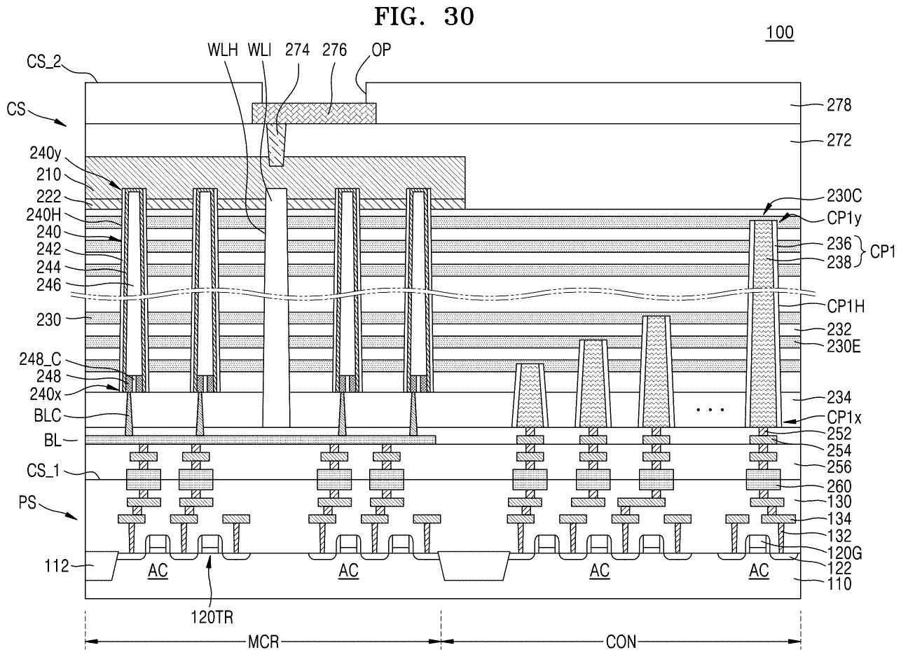

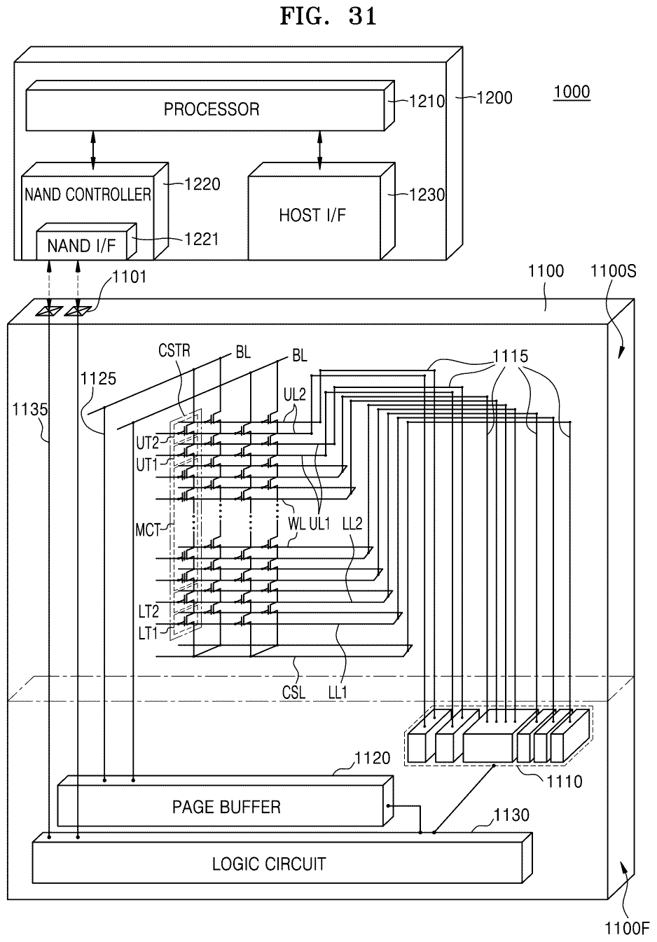

FIG. 31 is a diagram schematically illustrating a data storage system 1000 including a semiconductor device according to embodiments.

Referring to FIG. 31, a data storage system 1000 may include one or more semiconductor devices 1100 and a memory controller 1200 electrically connected to the semiconductor devices 1100. The data storage system 1000 may be, for example, a solid state drive device (SSD) including at least one semiconductor device 1100, a universal serial bus (USB), a computing system, a medical device, or a communication device.

The semiconductor device 1100 may be a nonvolatile semiconductor device, and for example, the semiconductor device 1100 may be a NAND flash semiconductor device including one of the semiconductor devices 100, 100A, 100B, 100C, and 100D described above. The semiconductor device 1100 may include a first structure 1100F and a second structure 1100S on the first structure 1100F. The first structure 1100F may include a peripheral circuit structure including a row decoder 1110, a page buffer 1120, and a logic circuit 1130.

The second structure 1100S may include a memory cell structure including a bit line BL, a common source line CSL, a plurality of word lines WL, first and second string selection lines UL1 and UL2, first and second ground selection lines LL1 and LL2, and a plurality of memory cell strings CSTR between the bit line BL and the common source line CSL.

In the second structure 1100S, the plurality of memory cell strings CSTR may include ground selection transistors LT1 and LT2 adjacent to the common source line CSL, string selection transistors UT1 and UT2 adjacent to the bit line BL, and a plurality of memory cell transistors MCT arranged between the ground selection transistors LT1 and LT2 and the string selection transistors UT1 and UT2, respectively. The number of the ground selection transistors LT1 and LT2 and the number of the string selection transistors UT1 and UT2 may be variously modified according to embodiments.

In embodiments, the plurality of ground selection lines LL1 and LL2 may be connected to the gate electrodes of the ground selection transistors LT1 and LT2, respectively. The word lines WL may be connected to the gate electrodes of the memory cell transistors MCT. The plurality of string selection lines UL1 and UL2 may be connected to the gate electrodes of the string selection transistors UT1 and UT2, respectively.

The common source line CSL, the plurality of ground selection lines LL1 and LL2, the plurality of word lines WL, and the plurality of string selection lines UL1 and UL2 may be connected to a row decoder 1110. A plurality of bit lines BL may be electrically connected to a page buffer 1120.

The semiconductor device 1100 may communicate with a memory controller 1200 through an input/output pad 1101 electrically connected to a logic circuit 1130. The input/output pad 1101 may be electrically connected to the logic circuit 1130.

The memory controller 1200 may include a processor 1210, a NAND controller 1220, and a host interface 1230. In some embodiments, the data storage system 1000 may include the plurality of semiconductor devices 1100, and in this case, the memory controller 1200 may control the plurality of semiconductor devices 1100.

The processor 1210 may control the overall operation of the data storage system 1000 including the memory controller 1200. The processor 1210 may operate according to a predetermined firmware and may access the semiconductor device 1100 by controlling the NAND controller 1220. The NAND controller 1220 may include a NAND interface 1221 that processes communication with the semiconductor devices 1100. A control command for controlling the semiconductor devices 1100, data to be written in the plurality of memory cell transistors MCT of the semiconductor devices 1100, data to be read from the plurality of memory cell transistors MCT of the semiconductor devices 1100, and the like may be transmitted through the NAND interface 1221. A host interface 1230 may provide a communication function between the data storage system 1000 and an external host. When a control command is received from an external host through the host interface 1230, the processor 1210 may control the semiconductor devices 1100 in response to the control command.

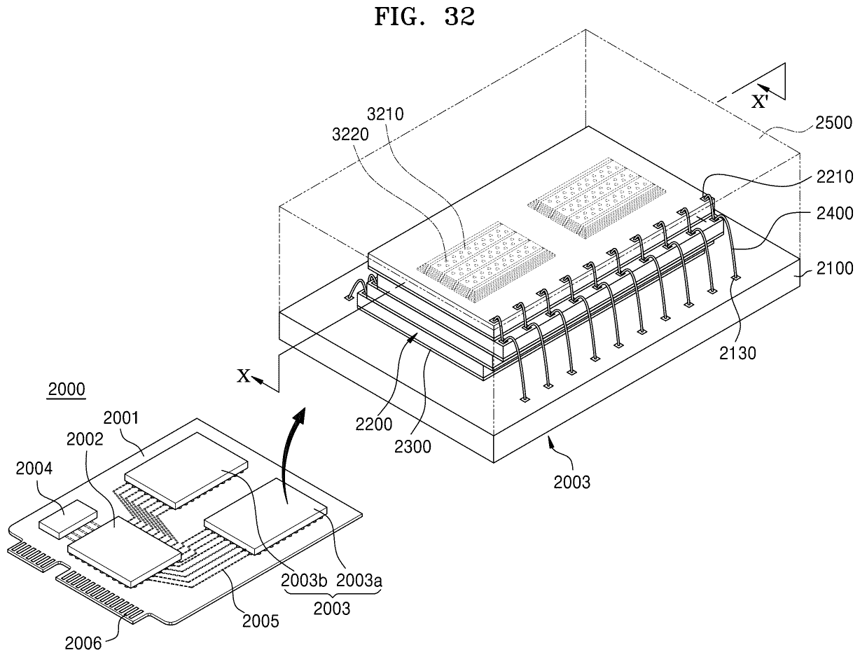

FIG. 32 is a perspective view schematically illustrating a data storage system 2000 including a semiconductor device according to embodiments.

Referring to FIG. 32, a data storage system 2000 according to an embodiment may include a main board 2001, a memory controller 2002 mounted on the main board 2001, one or more semiconductor packages 2003, and a dynamic random access memory (DRAM) 2004. The semiconductor packages 2003 and the DRAM 2004 may be connected to the memory controller 2002 by a plurality of wiring patterns 2005 formed on the main board 2001.

The main board 2001 may include a connector 2006 including a plurality of pins coupled to an external host. The number and arrangement of the plurality of pins in the connector 2006 may vary depending on the communication interface between the data storage system 2000 and the external host. In embodiments, the data storage system 2000 may communicate with an external host according to any one of interfaces such as Universal Serial Bus (USB), Peripheral Component Interconnect Express (PCI-Express), Serial Advanced Technology Attachment (SATA), and M-Phy for Universal Flash Storage (UFS). In embodiments, the data storage system 2000 may operate by power supplied from an external host via the connector 2006. The data storage system 2000 may further include a power management integrated circuit (PMIC) that distributes power supplied from the external host to the memory controller 2002 and the semiconductor package 2003.

The memory controller 2002 may write data in the semiconductor package 2003 or read data from the semiconductor package 2003, and may improve the operating speed of the data storage system 2000.

The DRAM 2004 may be a buffer memory for mitigating a speed difference between the semiconductor package 2003 that is a data storage space and an external host. The DRAM 2004 included in the data storage system 2000 may also operate as a kind of cache memory, and may provide a space for temporarily storing data in a control operation for the semiconductor package 2003. When the data storage system 2000 includes the DRAM 2004, the memory controller 2002 may further include a DRAM controller for controlling the DRAM 2004 in addition to a NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package board 2100, a plurality of semiconductor chips 2200 on the package board 2100, an adhesive layer 2300 arranged on the bottom surface of each of the plurality of semiconductor chips 2200, a connection structure 2400 electrically connecting the plurality of semiconductor chips 2200 to the package board 2100, and a molding layer 2500 covering the plurality of semiconductor chips 2200 and the connection structure 2400 on the package board 2100.

The package board 2100 may be a printed circuit board including a plurality of package upper pads 2130. Each of the plurality of semiconductor chips 2200 may include an input/output pad 2210. The input/output pad 2210 may correspond to the input/output pad 1101 of FIG. 31. Each of the plurality of semiconductor chips 2200 may include at least one of the semiconductor devices 100, 100A, 100B, 100C, and 100D described above.

In embodiments, the connection structure 2400 may be a bonding wire electrically connecting the input/output pad 2210 to the package upper pad 2130. Thus, in the first and second semiconductor packages 2003a and 2003b, the plurality of semiconductor chips 2200 may be electrically connected to each other in a bonding wire manner, and may be electrically connected to the package upper pad 2130 of the package board 2100. In embodiments, in the first and second semiconductor packages 2003a and 2003b, the plurality of semiconductor chips 2200 may be electrically connected to each other by a connection structure including a through silicon via (TSV) instead of the bonding wire type connection structure 2400.

In embodiments, the memory controller 2002 and the plurality of semiconductor chips 2200 may be included in a single package. In an embodiment, the memory controller 2002 and the plurality of semiconductor chips 2200 may be mounted on a separate interposer board different from the main board 2001, and the memory controller 2002 and the plurality of semiconductor chips 2200 may be connected to each other by a wiring formed on the interposer board.

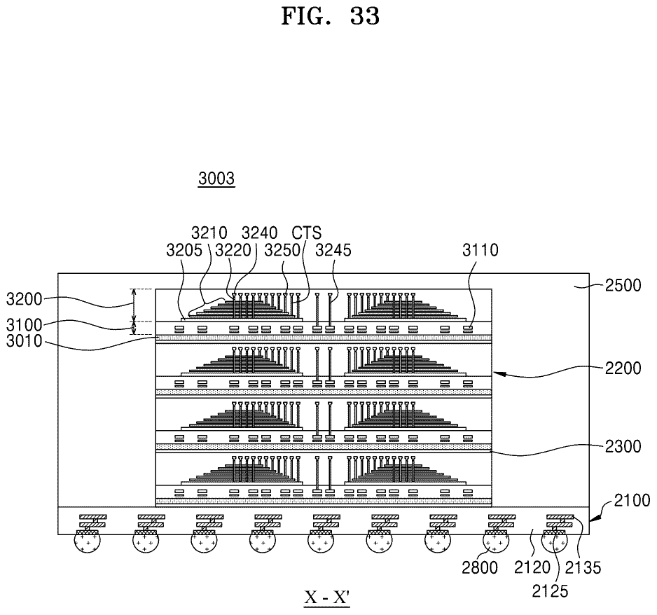

FIG. 33 is a cross-sectional view schematically illustrating semiconductor packages 2003 according to embodiments. FIG. 33 is a cross-sectional view taken along line X-X′ of FIG. 32.

Referring to FIG. 33, in a semiconductor package 2003, a package board 2100 may be a printed circuit board. The package board 2100 may include a package board body part 2120, a plurality of package upper pads 2130 (see FIG. 32) arranged on the top surface of the package board body part 2120, a plurality of lower pads 2125 arranged on or exposed through the bottom surface of the package board body part 2120, and a plurality of internal wires 2135 electrically connecting the plurality of package upper pads 2130 (see FIG. 32) to a plurality of lower pads 2125 inside the package board body part 2120. As shown in FIG. 33, the plurality of package upper pads 2130 may be electrically connected to a plurality of connection structures 2400. The plurality of lower pads 2125 may be connected to a plurality of wiring patterns 2005 on the main board 2001 of the data storage system 2000 shown in FIG. 32 through a plurality of conductive bumps 2800. Each of the plurality of semiconductor chips 2200 may include at least one of the semiconductor devices 100, 100A, 100B, 100C, and 100D described above.

While the inventive concept has been particularly shown and described with reference to embodiments thereof, it will be understood that various changes in form and details may be made therein without departing from the spirit and scope of the following claims.

What is claimed is:

1. A semiconductor device comprising:
a plurality of gate electrodes and a plurality of mold insulating layers arranged alternately with each other in a vertical direction on a substrate; and
a channel structure arranged in a channel hole extending in the vertical direction through the plurality of gate electrodes, wherein the channel structure comprises:
a gate insulating layer arranged on an inner wall of the channel hole;
a channel layer arranged on an inner wall of the gate insulating layer and having an inner wall consisting of a first portion and a second portion;
a buried insulating layer covering the first portion of an inner wall of the channel layer;
a plurality of drain patterns covering the second portion of the inner wall of the channel layer and spaced apart from each other in a horizontal direction; and
a drain region cut arranged between the plurality of drain patterns to electrically separate the plurality of drain patterns from each other,
wherein one end of the drain region cut is in contact with the buried insulating layer in the vertical direction.

2. The semiconductor device of claim 1, wherein:
the channel hole comprises a pair of first regions facing each other in a first horizontal direction and a pair of second regions facing each other in a second horizontal direction crossing the first horizontal direction,
the channel layer comprises a first channel pattern and a second channel pattern spaced apart from each other,
the first channel pattern and the second channel pattern are arranged on the pair of second regions of the channel hole, respectively, and
the drain region cut is arranged between the first channel pattern and the second channel pattern.

3. The semiconductor device of claim 2, wherein the channel hole has a first width in the second horizontal direction that is greater than a second width in the first horizontal direction.

4. The semiconductor device of claim 2, wherein:
the plurality of drain patterns comprise a first drain pattern and a second drain pattern,
the first drain pattern is arranged between the first channel pattern and a first sidewall of the drain region cut, and
the second drain pattern is arranged between the second channel pattern and a second sidewall of the drain region cut.

5. The semiconductor device of claim 1, wherein:
the channel hole comprises a plurality of first regions each having a first curvature and a plurality of second regions each having a second curvature greater than the first curvature,
the channel layer comprises a plurality of channel patterns spaced apart from each other,
the plurality of channel patterns are arranged on the plurality of second regions of the channel hole, respectively, and
the drain region cut is arranged between the plurality of channel patterns.

6. The semiconductor device of claim 1, wherein:
the drain region cut extends in a first horizontal direction, and
the semiconductor device further comprises a bit line extending in a second horizontal direction crossing the first horizontal direction.

7. The semiconductor device of claim 1, wherein:
the plurality of drain patterns are spaced apart from each other in a first horizontal direction, and
the semiconductor device further comprises a bit line extending in a second horizontal direction crossing the first horizontal direction.

8. The semiconductor device of claim 1, wherein the gate insulating layer comprises:
a blocking dielectric layer arranged on the inner wall of the channel hole;
a charge storage layer arranged on an inner wall of the blocking dielectric layer; and
a tunneling dielectric layer arranged on an inner wall of the charge storage layer, wherein
the blocking dielectric layer comprises a first blocking dielectric pattern and a second blocking dielectric pattern, and
the first blocking dielectric pattern and the second blocking dielectric pattern are spaced apart from each other in the horizontal direction.

9. The semiconductor device of claim 1, wherein the gate insulating layer comprises:
a blocking dielectric layer arranged on the inner wall of the channel hole;
a charge storage layer arranged on an inner wall of the blocking dielectric layer; and
a tunneling dielectric layer arranged on an inner wall of the charge storage layer, wherein
the charge storage layer comprises a first charge storage pattern and a second charge storage pattern, and
the first charge storage pattern and the second charge storage pattern are spaced apart from each other in the horizontal direction.

10. The semiconductor device of claim 1, wherein the gate insulating layer comprises:
a blocking dielectric layer arranged on the inner wall of the channel hole;
a charge storage layer arranged on an inner wall of the blocking dielectric layer; and
a tunneling dielectric layer arranged on an inner wall of the charge storage layer, wherein
the tunneling dielectric layer comprises a first tunneling dielectric pattern and a second tunneling dielectric pattern, and
the first tunneling dielectric pattern and the second tunneling dielectric pattern are spaced apart from each other in the horizontal direction.

11. A semiconductor device comprising:
a peripheral circuit structure; and
a cell structure arranged on the peripheral circuit structure, wherein the cell structure comprises:
a plurality of gate electrodes and a plurality of mold insulating layers alternately arranged in a vertical direction on a top surface of the peripheral circuit structure; and
a channel structure arranged in a channel hole extending in the vertical direction through the plurality of gate electrodes, wherein the channel structure comprises:
a gate insulating layer arranged on an inner wall of the channel hole;
a first channel pattern and a second channel pattern, arranged on an inner wall of the gate insulating layer; and
a buried insulating layer arranged on an inner wall of each of the first channel pattern and the second channel pattern, wherein:
the channel hole includes a pair of first regions facing each other in a first horizontal direction and a pair of second regions facing each other in a second horizontal direction crossing the first horizontal direction,
the first channel pattern and the second channel pattern are respectively arranged on the pair of second regions of the channel hole and spaced apart from each other in the second horizontal direction, and
each of the first channel pattern and the second channel pattern has a shape in which a thickness decreases from a center portion toward an edge portion in a layout.

12. The semiconductor device of claim 11, wherein the channel hole has a second width in the second horizontal direction greater than a first width in the first horizontal direction.

13. The semiconductor device of claim 11, wherein:
each of the pair of first regions of the channel hole has a first curvature, and
each of the pair of second regions of the channel hole has a second curvature greater than the first curvature.

14. The semiconductor device of claim 11, further comprising a bit line electrically connected to the channel structure, wherein the bit line extends in the first horizontal direction.

15. The semiconductor device of claim 11, further comprising a bit line electrically connected to the channel structure, wherein the bit line extends in the second horizontal direction.

16. The semiconductor device of claim 11, wherein:
the channel structure further comprises a first drain pattern and a second drain pattern, which are arranged on the buried insulating layer,
the first channel pattern and the second channel pattern, each having an inner wall consisting of a first portion and a second portion,
the buried insulating layer covers the first portion of the inner wall of each of the first channel pattern and the second channel pattern, and
the first drain pattern and the second drain pattern cover the second portion of the inner wall of each of the first channel pattern and the second channel pattern.

17. The semiconductor device of claim 16, further comprising:
a plurality of connection pads arranged between the peripheral circuit structure and the cell structure to electrically connect the peripheral circuit structure and the cell structure to each other;
a plurality of bit lines electrically connected to the plurality of connection pads; and
a plurality of bit line contacts electrically connecting a first bit line among the plurality of bit lines to the first drain pattern and electrically connecting a second bit line among the plurality of bit lines to the second drain pattern.

18. A semiconductor device comprising:
a peripheral circuit structure; and
a cell structure arranged on the peripheral circuit structure and including a cell region and a connection region, wherein the cell structure comprises:
a plurality of gate electrodes and a plurality of mold insulating layers alternately arranged in a vertical direction on a top surface of the peripheral circuit structure in the cell region and the connection region;
a channel structure arranged in a channel hole extending in the vertical direction through the plurality of gate electrodes, in the cell region;
a stack cover insulating layer arranged under a lowermost gate electrode among the plurality of gate electrodes, in the cell region and the connection region; and
a cell plug being in contact with a first gate electrode of the plurality of gate electrodes in the connection region, and arranged in a cell plug hole passing through a second gate electrode of the plurality of gate electrodes, the second gate electrode being arranged under the first gate electrode among the plurality of gate electrodes,
wherein the channel structure comprises:
a gate insulating layer arranged on an inner wall of the channel hole;
a first channel pattern and a second channel pattern, arranged on an inner wall of the gate insulating layer and spaced apart from each other in a horizontal direction;
a buried insulating layer arranged on an inner wall of each of the first channel pattern and the second channel pattern to cover an upper portion of the inner wall of each of the first channel pattern and the second channel pattern;
a first drain pattern and a second drain pattern, arranged on the inner walls of the first channel pattern and the second channel pattern to cover lower portions of the inner walls of the first channel pattern and the second channel pattern, and spaced apart from each other in the horizontal direction; and
a drain region cut separating the first drain pattern from the second drain pattern, wherein
a first end of the drain region cut is in contact with the buried insulating layer in the vertical direction.

19. The semiconductor device of claim 18, wherein:
the channel hole includes a pair of first regions facing each other in a first horizontal direction and a pair of second regions facing each other in a second horizontal direction crossing the first horizontal direction, and
the first channel pattern and the second channel pattern are arranged on the pair of second regions of the channel hole, respectively.

20. The semiconductor device of claim 19, wherein the gate insulating layer comprises:
a blocking dielectric layer arranged on the inner wall of the channel hole;
a charge storage layer arranged on an inner wall of the blocking dielectric layer; and
a tunneling dielectric layer arranged on an inner wall of the charge storage layer, wherein
the charge storage layer comprises a first charge storage pattern and a second charge storage pattern, and
the first charge storage pattern and the second charge storage pattern are arranged on the pair of second regions of the channel hole, respectively.
